(19) United States
(12) Patent Application Publication
(10) Pub. No.: US 2025/0367900 A1
(43) Pub. Date: Dec. 4, 2025

(54) LAMINATE

(71) Applicant: FUJIFILM CORPORATION, Tokyo (JP)

(72) Inventor: Yuichi Kasuya, Shizuoka (JP)

(21) Appl. No.: 19/297,871

(22) Filed: Aug. 12, 2025

Related U.S. Application Data
(63) Continuation of application No. PCT/JP2024/036597, filed on Oct. 15, 2024.

(30) Foreign Application Priority Data
Mar. 26, 2024 (JP) 2024-049184

(51) Int. Cl. B32B 3/18; B32B 7/12; B32B 15/04

(52) U.S. Cl. CPC B32B 3/18; B32B 7/12; B32B 15/043; B32B 2307/202; B32B 2307/206; B32B 2307/72; B32B 2307/7376

(57) ABSTRACT

Provided is a laminate including an anisotropically conductive member which is easy to handle in a case of being individualized. The laminate includes a support, an adhesive layer, and an anisotropically conductive member, in which the support, the adhesive layer, and the anisotropically conductive member are laminated in this order, the anisotropically conductive member has an insulating base material having electrical insulating properties and a plurality of conduction paths which penetrate in a thickness direction of the insulating base material and are provided in a state of being electrically insulated from each other, each of the plurality of the conduction paths is composed of a conductive substance, in which a diameter of one surface in the thickness direction of the insulating base material is different from a diameter of the other surface in the thickness direction of the insulating base material, and in a case where a value of small diameter/large diameter, which is a ratio of a small diameter and a large diameter between the diameter of the one surface of the conduction path and the diameter of the other surface of the conduction path, is denoted by R, 0.1≤R≤0.98 is satisfied.

### CROSS-REFERENCE TO RELATED APPLICATIONS

This application is a Continuation of PCT International Application No. PCT/JP2024/036597 filed on Oct. 15, 2024, which claims priority under 35 U.S.C. § 119(a) to Japanese Patent Application No. 2024-049184 filed on Mar. 26, 2024. The above applications are hereby expressly incorporated by reference, in their entirety, into the present application.

### BACKGROUND OF THE INVENTION

### 1. Field of the Invention

The present invention relates to a laminate in which a support, an adhesive layer, and an anisotropically conductive member are laminated in this order, in particular, a laminate in which diameters of conduction paths of anisotropically conductive members are different on a surface facing each other.

### 2. Description of the Related Art

There is an anisotropically conductive member having a conduction path in which a plurality of through-holes provided in an insulating base material are filled with a conductive substance such as metal.

In a case where the anisotropically conductive member is inserted between an electronic component such as a semiconductor element and a circuit board and is simply pressurized, an electrical connection between the electronic component and the circuit board can be obtained, so that the anisotropically conductive bonding member has been widely used as an electrical connecting member of the electronic component or the like such as a semiconductor element or used as a testing connector thereof for carrying out a functional test.

In particular, an electronic component such as a semiconductor element is significantly downsized. In a method of directly connecting a wiring board such as a wire bonding in the related art, flip chip bonding, thermocompression bonding, and the like, stability of electrical connection of the electronic component may not be sufficiently guaranteed, and thus, an anisotropically conductive member has been attracting attention as an electronic connection member.

As the anisotropically conductive member, for example, JP2018-037509A discloses an anisotropically conductive bonding member including an insulating base material consisting of an inorganic material, a plurality of conduction paths consisting of conductive members, and a resin layer provided on the entire surface of the insulating base material. The conduction path penetrates the insulating base material in a thickness direction in a state of being insulated from each other. The conduction path has a protruding portion which is parallel to each other and protrudes from the surface of the insulating base material, and an end part of the protruding portion is embedded in the resin layer.

### SUMMARY OF THE INVENTION

In a case where the anisotropically conductive bonding member of JP2018-037509A described above is used as the electronic connection member, the anisotropically conductive bonding member is provided for each semiconductor element to be connected. Therefore, it is necessary to set the size of the anisotropically conductive bonding member to a size corresponding to the size of the semiconductor element. Therefore, the anisotropically conductive bonding member of JP2018-037509A is separated into individual pieces having sizes corresponding to the size of the semiconductor element.

In a case where a semiconductor element and a circuit board are electrically connected to each other using the individualized anisotropically conductive bonding member, it is necessary to transfer the individualized anisotropically conductive bonding member to, for example, a predetermined position of the circuit board. However, it is difficult to grip and transport the individualized anisotropically conductive bonding member without damaging the anisotropically conductive bonding member. Therefore, it is desired to have a member which is excellent in handling, such as being able to be gripped or transported without being damaged in a case where the anisotropically conductive bonding member is separated into individual pieces.

An object of the present invention is to provide a laminate including an anisotropically conductive member which is easy to handle in a case of being individualized.

In order to achieve the above-described object, the invention [1] is a laminate including a support, an adhesive layer, and an anisotropically conductive member, in which the support, the adhesive layer, and the anisotropically conductive member are laminated in this order, the anisotropically conductive member has an insulating base material having electrical insulating properties and a plurality of conduction paths which penetrate in a thickness direction of the insulating base material and are provided in a state of being electrically insulated from each other, each of the plurality of the conduction paths is composed of a conductive substance, in which a diameter of one surface in the thickness direction of the insulating base material is different from a diameter of the other surface in the thickness direction of the insulating base material, and in a case where a value of small diameter/large diameter, which is a ratio of a small diameter and a large diameter between the diameter of the one surface of the conduction path and the diameter of the other surface of the conduction path, is denoted by R, 0.1≤R≤0.98 is satisfied.

The invention [2] is the laminate according to the invention [1], in which the anisotropically conductive member is laminated such that a surface on a side having the large diameter between the diameter of the one surface of the conduction path and the diameter of the other surface of the conduction path faces the adhesive layer.

The invention [3] is the laminate according to the invention [1] or [2], in which an adhesive force of the adhesive layer decreases in a specific temperature range, or decreases due to ultraviolet rays.

The invention [4] is the laminate according to the invention [3], in which the adhesive force of the adhesive layer decreases at a temperature of 110° C. or higher.

The invention [5] is the laminate according to any one of the inventions [1] to [4], in which the insulating base material is an anodized film of a valve metal.

The invention [6] is the laminate according to any one of the inventions [1] to [5], in which a density of the conduction paths in the one surface and the other surface of the insulating base material is 1×10⁶ to 1×10¹⁰/mm², and the diameter of the conduction path is 10 nm or more and 500 nm or less.

The invention [7] is the laminate according to any one of the inventions [1] to [6], in which a thickness of the insulating base material is 10 μm or more and 30 μm or less.

The invention [8] is the laminate according to any one of the inventions [1] to [7], in which the value R of small diameter/large diameter in the insulating base material is 0.1≤R≤0.95.

The invention [9] is the laminate according to any one of the inventions [1] to [8], in which the support is a bonding member having a metal layer, and the metal layer is exposed from the adhesive layer.

The invention [10] is the laminate according to any one of the inventions [1] to [9], in which the anisotropically conductive member has a crack in the insulating base material.

The invention [11] is the laminate according to any one of the inventions [1] to [10], in which the conduction path has a protruding portion which protrudes from at least one surface of facing surfaces of the insulating base material in the thickness direction.

According to the present invention, it is possible to provide a laminate including an anisotropically conductive member which is easy to handle in a case of being individualized.

### BRIEF DESCRIPTION OF THE DRAWINGS

FIG. 1 is a schematic cross-sectional view showing a first example of the laminate according to the embodiment of the present invention.

FIG. 2 is a schematic plan view showing the first example of the laminate according to the embodiment of the present invention.

FIG. 3 is a schematic plan view showing an example of a cutting form of the first example of the laminate according to the embodiment of the present invention.

FIG. 4 is a schematic view showing an example of an individualized anisotropically conductive member.

FIG. 5 is a schematic plan view showing another example of the anisotropically conductive member in the first example of the laminate according to the embodiment of the present invention.

FIG. 6 is a schematic cross-sectional view showing a second example of the laminate according to the embodiment of the present invention.

FIG. 7 is a schematic cross-sectional view showing one step of an example of a method for manufacturing the laminate according to the embodiment of the present invention.

FIG. 8 is a schematic cross-sectional view showing one step of the example of the method for manufacturing the laminate according to the embodiment of the present invention.

FIG. 9 is a schematic cross-sectional view showing one step of the example of the method for manufacturing the laminate according to the embodiment of the present invention.

FIG. 10 is a schematic cross-sectional view showing one step of the example of the method for manufacturing the laminate according to the embodiment of the present invention.

FIG. 11 is a schematic cross-sectional view showing one step of the example of the method for manufacturing the laminate according to the embodiment of the present invention.

FIG. 12 is a schematic cross-sectional view showing one step of the example of the method for manufacturing the laminate according to the embodiment of the present invention.

FIG. 13 is a schematic cross-sectional view showing one step of the example of the method for manufacturing the laminate according to the embodiment of the present invention.

FIG. 14 is a schematic cross-sectional view showing one step of the example of the method for manufacturing the laminate according to the embodiment of the present invention.

FIG. 15 is a schematic cross-sectional view showing one step of the example of the method for manufacturing the laminate according to the embodiment of the present invention.

### DESCRIPTION OF THE PREFERRED EMBODIMENTS

Hereinafter, the laminate according to the embodiment of the present invention will be described in detail based on suitable embodiments shown in the accompanying drawings.

The drawings described below are exemplary for describing the present invention and are simplified for describing the present invention. Therefore, the present invention is not limited to the drawings described below.

In the following, “to” indicating the numerical range includes numerical values described on both sides. For example, in a case where ε is a numerical value ε_{α} to a numerical value ε_{β}, the range of ε is a range including the numerical value ε_{α} and the numerical value ε_{β}, and in mathematical symbols, ε_{α}≤ε≤ε_{β}.

Unless otherwise specified, a term “parallel” includes an error range generally allowed in the relevant technical field.

Unless otherwise specified, a temperature and a time include error ranges generally allowed in the relevant technical field.

In addition, a term “same” includes an error range is generally allowed in the relevant technical field. In addition, a term “entire surface” or the like includes an error range is generally allowed in the relevant technical field.

Hereinafter, the laminate will be specifically described.

### First Example of Laminate

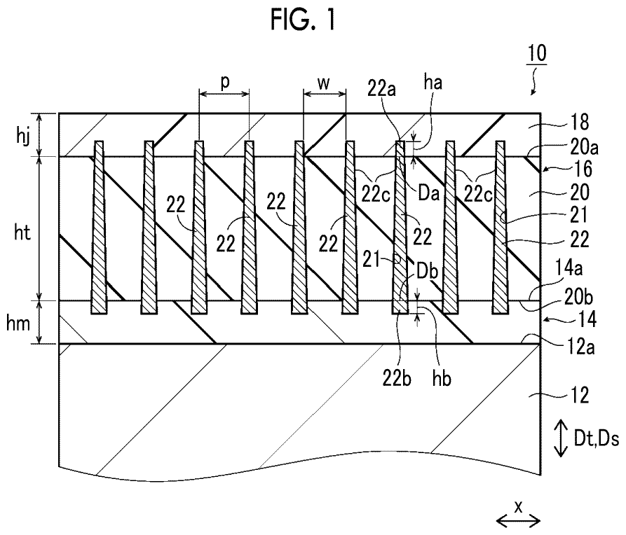

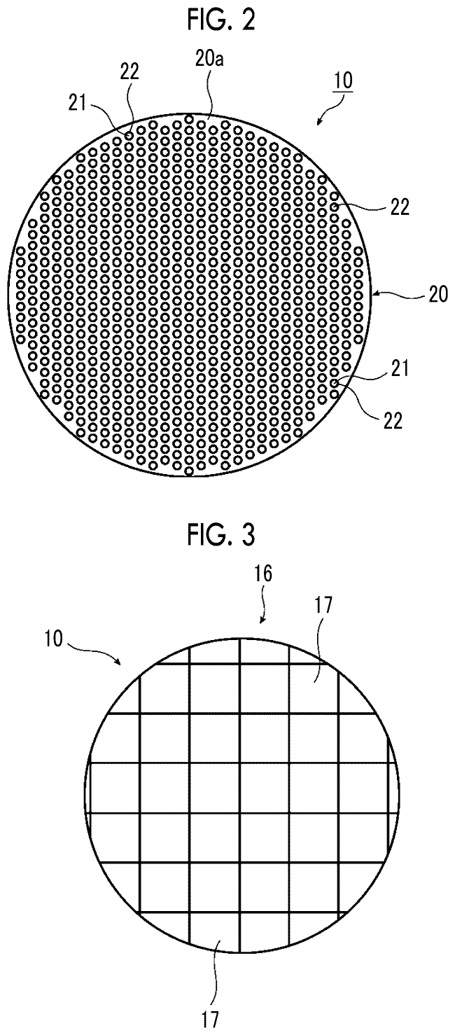

FIG. 1 is a schematic cross-sectional view showing a first example of the laminate according to the embodiment of the present invention, and FIG. 2 is a schematic plan view showing the first example of the laminate according to the embodiment of the present invention. FIG. 2 is a plan view of FIG. 1 as viewed from a front surface 20a side of an insulating base material 20, shows a state in which a resin layer 18 is not present.

A laminate 10 shown in FIG. 1 is a laminate in which a support 12, an adhesive layer 14, and an anisotropically conductive member 16 are laminated in this order. The adhesive layer 14 is provided on a front surface 12a of the support 12, and the anisotropically conductive member 16 is provided on a surface 14a of the adhesive layer 14. The laminate 10 further includes a resin layer 18 on the anisotropically conductive member 16.

A direction in which the support 12, the adhesive layer 14, and the anisotropically conductive member 16 are laminated is a lamination direction Ds.

The support 12 supports the anisotropically conductive member 16. By providing the support 12, handling of the anisotropically conductive member 16 is improved as compared with a case where the anisotropically conductive member 16 is handled alone. It is preferable that the support 12 has stiffness and size which allow the support 12 to be transported by a machine using an arm, a transport holding device, or the like.

Here, the handling is to grip and hold the anisotropically conductive member 16, and to move the anisotropically conductive member 16, such as transporting, conveying, and carrying the anisotropically conductive member 16. Handling of an anisotropically conductive member 17 obtained by individually separating the anisotropically conductive member 16 is the same as that of the anisotropically conductive member 16.

The improved handling means that damage or the like to the anisotropically conductive member 16 can be suppressed in a case of gripping and holding the anisotropically conductive member 16 and in a case of moving, conveying, or carrying the anisotropically conductive member 16.

From the viewpoint of handleability such as transport and installation on various processing devices, it is preferable that the support 12 has the same outer shape and size as the outer shape and size of the anisotropically conductive member 16. In this case, in a case where the outer shape of the anisotropically conductive member 16 is a circular shape having a specific diameter, it is preferable that the outer shape of the support 12 is also the circular shape having a specific diameter.

The adhesive layer 14 adheres the support 12 and the anisotropically conductive member 16 to each other. In a case where a conduction path 22 of the anisotropically conductive member 16 has a protruding portion which protrudes from an insulating base material 20, the adhesive layer 14 functions as a protective layer for protecting the protruding portion.

In addition, in order to easily peel off the anisotropically conductive member 16 from the support 12, it is preferable that an adhesive force of the adhesive layer 14 decreases in a specific temperature range, or the adhesive force decreases due to ultraviolet rays. The adhesive layer 14 will be described later.

The anisotropically conductive member 16 has an insulating base material 20 having electrical insulating properties and a plurality of conduction paths 22 which penetrate in a thickness direction Dt of the insulating base material 20 and are provided in a state of being electrically insulated from each other.

In this case, for example, the insulating base material 20 has a plurality of pores 21 penetrating in the thickness direction Dt. The plurality of pores 21 are filled with a conductive substance to form the plurality of conduction paths 22. The conduction path 22 is a columnar conductor composed of a conductive substance and having electrical conductivity.

The anisotropically conductive member 16 has anisotropic conductivity and has conductivity in the thickness direction Dt, but has low conductivity in a direction x parallel to a front surface 20a of the insulating base material 20.

Here, the front surface 20a of the insulating base material 20 and a back surface 20b of the insulating base material 20 are surfaces facing each other in the thickness direction Dt of the insulating base material 20. The insulating base material 20 is composed of, for example, an anodized film of a valve metal.

For example, the conduction path 22 has a protruding portion 22a which protrudes from the front surface 20a of the insulating base material 20. The conduction path 22 has a protruding portion 22b which protrudes from the back surface 20b of the insulating base material 20. The protruding portion 22a of the conduction path 22 is embedded in the resin layer 18. The protruding portion 22b of the conduction path 22 is embedded in the adhesive layer 14.

The conduction path 22 is configured to have the protruding portion 22a and the protruding portion 22b, but the present invention is not limited thereto. The conduction path 22 may have a configuration in which a protruding portion which protrudes from at least one surface of surfaces facing each other in the thickness direction Dt of the insulating base material 20 is provided. That is, a configuration in which at least one of the protruding portion 22a or the protruding portion 22b is provided may be adopted. Furthermore, the conduction path 22 may have a configuration in which the protruding portion 22a and the protruding portion 22b are not provided.

As shown in FIG. 2, the laminate 10 has, for example, a circular outer shape. The outer shape of the laminate 10 is not limited to the circular shape and may be, for example, a quadrangular shape. The outer shape of the laminate 10 can be set to a shape according to the application, ease of production, and the like. In the laminate 10, for example, in a case where a silicon wafer is used as the support 12, the outer shape of the anisotropically conductive member 16 is circular.

In the anisotropically conductive member 16, each of the plurality of conduction paths 22 is composed of a conductive substance as described above, in which a diameter of one surface of the insulating base material 20 in the thickness direction Dt and a diameter of the other surface of the insulating base material 20 in the thickness direction Dt are different from each other. That is, in the conduction path 22, a diameter Da on the front surface 20a of the insulating base material 20 and a diameter Db on the back surface 20b of the insulating base material 20 are different from each other. In the anisotropically conductive member 16 shown in FIG. 1, there is a relationship of the diameter Da<the diameter Db, and the diameter Da is a small diameter and the diameter Db is a large diameter. The anisotropically conductive member 16 is laminated such that the back surface 20b of the insulating base material 20, which is a surface on the side where the diameter Db of the conduction path 22 is large, faces the adhesive layer 14.

As described above, in the conduction path 22, the diameter Da on the front surface 20a of the insulating base material 20 and the diameter Db on the back surface 20b of the insulating base material 20 are different from each other. A side surface 22c of the conduction path 22 is configured, for example, with an inclined surface with respect to the thickness direction Dt of the insulating base material 20, and does not have a bent portion or the like. In the cross section shown in FIG. 1, the side surface 22c is tapered in the thickness direction Dt such that an interval is continuously narrowed from the back surface 20b to the front surface 20a of the insulating base material 20. The side surface 22c is not particularly limited to the tapered configuration shown in FIG. 1.

In a case where the shape of the conduction path 22 on the front surface 20a of the insulating base material 20 is not a circle, the diameter Da on the front surface 20a of the insulating base material 20 is an equivalent circle diameter.

In addition, in a case where the shape of the conduction path 22 on the back surface 20b of the insulating base material 20 is not a circle, the diameter Db on the back surface 20b of the insulating base material 20 is an equivalent circle diameter.

The conduction path 22 shown in FIG. 1 has a configuration in which the protruding portion 22a and the protruding portion 22b are provided. Even in a case where the conduction path 22 has the protruding portion 22a and the protruding portion 22b, and even in a case where the conduction path 22 does not have the protruding portion 22a and the protruding portion 22b, the diameter Da is the diameter on the front surface 20a of the insulating base material 20, and the diameter Db is the diameter on the back surface 20b of the insulating base material 20.

In a case where a value of small diameter/large diameter, which is a ratio of a small diameter and a large diameter between a diameter of one surface of the conduction path 22 and a diameter of the other surface of the conduction path 22, is denoted by R, 0.1≤R≤0.98 is satisfied; and it is preferable to satisfy 0.1≤R≤0.95, it is more preferable to satisfy 0.1≤R≤0.85, and it is still more preferable to satisfy 0.5<R≤0.85.

The above-described value R of small diameter/large diameter is represented by R=Da/Db. In this case, 0.1≤R≤0.98 is 0.1Db≤Da≤0.98Db.

In a case where the value R of small diameter/large diameter is 0.1≤R≤0.98, a proportion of the conduction path 22 occupied in the front surface 20a and the back surface 20b of the insulating base material 20 is different. As a result, a difference occurs between a force acting on the front surface 20a of the insulating base material 20 and a force acting on the back surface 20b of the insulating base material 20. A difference in stress occurs between a stress generated on the front surface 20a of the insulating base material 20 and a stress generated on the back surface 20b of the insulating base material 20, based on the difference in force generated in the front surface 20a of the insulating base material 20 and in the back surface 20b of the insulating base material 20. The anisotropically conductive member 16 warps in a case of being separated into individual pieces based on the difference in stress. In a case where the individualized anisotropically conductive member 17 warps, a part of the anisotropically conductive member 17 floats away from an installation surface such as the surface of the support. As a result, the anisotropically conductive member is easily detachable and easily handled in a case of being separated into individual pieces. That is, the handling is improved.

In addition, in a case where the value R of small diameter/large diameter is 0.1≤R≤0.85, the anisotropically conductive member is further easily removed in a case of being separated into individual pieces, and thus the handling is further improved. In a case where the value R of small diameter/large diameter is 0.5<R≤0.85, quality of the anisotropically conductive member after taking out the individual pieces is improved, in addition to the fact that the anisotropically conductive member is easily removed and handled in a case of being separated into individual pieces.

Here, FIG. 3 is a schematic plan view showing an example of a cutting form of the first example of the laminate according to the embodiment of the present invention; and FIG. 4 is a schematic view showing an example of the individualized anisotropically conductive member. In FIGS. 3 and 4, the same components as those of the laminate 10 shown in FIGS. 1 and 2 are designated by the same reference numerals, and detailed description thereof will not be repeated. In FIG. 3, the resin layer 18 is not shown.

The anisotropically conductive member 16 of the laminate 10 shown in FIG. 3 is cut into, for example, a quadrangular shape using a laser or a dicing saw. As a result, the anisotropically conductive member 16 is separated into individual pieces. In the cut anisotropically conductive members 16, the individualized anisotropically conductive members 17 are independent of each other and are not constrained in a direction parallel to the front surface 20a (see FIG. 1) of the insulating base material 20.

After the anisotropically conductive member 16 is separated into individual pieces, for example, in a case where the adhesive layer 14 (see FIG. 1) has a property in which the adhesive force is weakened by temperature, a heat treatment is performed to weaken the adhesive force of the adhesive layer 14. As a result, the individualized anisotropically conductive member 17 has a small binding force to the support 12 by the adhesive layer 14, and thus the individualized anisotropically conductive member 17 can be easily detached from the support 12 (see FIG. 1). In this case, in a case where 0.1≤R≤0.98 as described above, the anisotropically conductive member 17 separated into individual pieces as shown in FIG. 4 warps due to the difference in stress based on the difference between the diameter Da on the front surface 20a of the insulating base material 20 and the diameter Db on the back surface 20b of the insulating base material 20. As shown in FIG. 4, the anisotropically conductive member 16 having the relationship of the diameter Da<the diameter Db is separated into individual pieces to be convexly warped with respect to the surface 12a of the support 12, and a part of the individualized anisotropically conductive member 17 floats away from the surface 12a of the support 12.

For example, in a case where the individualized anisotropically conductive members 17 on a chip tray are transported using a head (not shown) of a flip chip bonding device (not shown) or in a case where the individualized anisotropically conductive members 17 are transported using a head (not shown) of a chip mounter (not shown), the warped anisotropically conductive members 17 are more easily gripped by the head or the like and are easily removed than non-warped anisotropically conductive members, and thus the handling is excellent.

As described above, by setting 0.1≤R≤0.98 using the difference in stress generated by the difference between the diameter of one surface and the diameter of the other surface of the conduction path 22 in the anisotropically conductive member, the anisotropically conductive member 17 can be easily handled as a configuration in which the individualized anisotropically conductive member 17 is warped, and thus the handling can be improved.

The resin layer 18 shown in FIG. 1 is provided on the front surface 20a of the insulating base material 20, and for example, the entire front surface 20a is covered with the resin layer 18. In a case where the conduction path 22 has the protruding portion 22a, the protruding portion 22a is embedded in the resin layer 18. That is, the resin layer 18 covers an end part of the conduction path 22 which protrudes from the front surface 20a of the insulating base material 20, and protects the protruding portion 22a.

Hereinafter, the configuration of the laminate will be described in more detail.

### Support

The support 12 supports the anisotropically conductive member 16 as described above, and is composed of, for example, a silicon substrate. For the silicon substrate, for example, a so-called silicon wafer is used. As the support 12, in addition to the silicon substrate, for example, a ceramic substrate such as SiC, SiN, GaN, and alumina (Al₂O₃), a glass substrate, a fiber reinforced plastic substrate, or a metal substrate can be used. The fiber reinforced plastic substrate includes a flame retardant type 4 (FR-4) substrate which is a printed wiring board.

In addition, as the support 12, a flexible and transparent support can be used. Examples of the flexible and transparent support 12 include plastic films such as polyethylene terephthalate (PET), polycycloolefin, polycarbonate, an acrylic resin, polyethylene naphthalate (PEN), polyethylene (PE), polypropylene (PP), polystyrene, polyvinyl chloride, polyvinylidene chloride, and triacetyl cellulose (TAC).

Here, the “transparent” means that a light transmittance is 80% or more at a wavelength which is used for registration. For this reason, the transmittance may be low in the entire visible light range of a wavelength of 400 to 800 nm, and the transmittance is preferably 80% or more in the entire visible light range of a wavelength of 400 to 800 nm. The transmittance is measured with a spectrophotometer.

In a case where a material having a decreased adhesive force due to ultraviolet rays is used for the adhesive layer 14, it is preferable that the support 12 is transparent as described above, that is, the transmittance of the support 12 to ultraviolet rays is 80% or more, because ultraviolet rays are easily applied to the adhesive layer 14.

Here, the ultraviolet rays are light having a wavelength of 10 to 400 nm. A preferred wavelength range of the ultraviolet rays is 200 to 400 nm, and a more preferred wavelength range of the ultraviolet rays is 300 to 400 nm.

### Adhesive Layer

It is preferable that the adhesive layer has an adhesive force which decreases in a specific temperature range or an adhesive force which decreases due to ultraviolet rays. For example, the adhesive layer is preferably a film with a peelable pressure-sensitive adhesive layer, and more preferably a film with a peelable pressure-sensitive adhesive layer, which has weakened adhesiveness and can be peeled off by a treatment for setting a specific temperature range or an ultraviolet exposure treatment.

In addition, for example, an adhesive layer in which the adhesive force decreases at a temperature of 110° C. or higher is used.

The above-described film with a pressure-sensitive adhesive layer is not particularly limited, and examples thereof include a heat-peeling type resin layer and an ultraviolet (UV)-peeling type resin layer.

Here, the heat-peeling type resin layer has adhesive force at normal temperature and is simply peelable by only heating, and in many cases, foaming microcapsules or the like are used.

In addition, specific examples of a pressure sensitive adhesive constituting the pressure-sensitive adhesive layer include a rubber-based pressure sensitive adhesive, an acrylic-based pressure sensitive adhesive, a vinyl alkyl ether-based pressure sensitive adhesive, a silicone-based pressure sensitive adhesive, a polyester-based pressure sensitive adhesive, a polyamide-based pressure sensitive adhesive, an urethane-based pressure sensitive adhesives, and a styrene-diene block copolymer-based pressure sensitive adhesive.

In addition, the UV-peeling type resin layer is a UV-curing type adhesive layer, and the adhesive force is lost by curing to be peelable.

Examples of the UV-curing type adhesive layer include a polymer obtained by introducing a carbon-carbon double bond into a polymer side chain or a polymer main chain or at the terminal of a main chain of a base polymer. The base polymer having a carbon-carbon double bond preferably has an acrylic polymer as a basic skeleton.

Furthermore, since the acrylic polymer can be crosslinked, a polyfunctional monomer or the like can be included as a monomer component for copolymerization as necessary.

The base polymer having a carbon-carbon double bond can be used alone, but a UV-curable monomer or oligomer can also be blended.

It is preferable to use a photopolymerization initiator in combination with the UV-curing type adhesive layer in order to cure the adhesive layer by UV irradiation. Examples of the photopolymerization initiator include a benzoin ether-based compound, a ketal-based compound, an aromatic sulfonyl chloride-based compound, a photoactive oxime-based compound, a benzophenone-based compound, a thioxanthone-based compound, camphorquinone, halogenated ketone, acyl phosphinoxide, and acyl phosphonate.

Examples of a commercially available product of the heat-peeling type resin layer include Intellimar [registered trade mark] tapes (manufactured by NITTA Corporation) such as WS5130C02 and WS5130C10; Somatac [registered trade mark] TE series (manufactured by SOMAR Corporation); and REVALPHA [registered trade mark] series (manufactured by Nitto Denko Corporation) such as No. 3198, No. 3198LS, No. 3198M, No. 3198MS, No. 3198H, No. 3195, No. 3196, No. 3195M, No. 3195MS, No. 3195H, No. 3195HS, No. 3195V, No. 3195VS, No. 319Y-4L, No. 319Y-4LS, No. 319Y-4M, No. 319Y-4MS, No. 319Y-4H, No. 319Y-4HS, No. 319Y-4LSC, No. 31935MS, No. 31935HS, No. 3193M, and No. 3193MS.

As a commercially available product of the UV-peeling type resin layer, for example, dicing tapes such as ELEP HOLDER [registered trade mark] (manufactured by Nitto Denko Corporation) including ELP DU-300, ELP DU-2385KS, ELP DU-2187G, ELP NBD-3190K, and ELP UE-2091J, Adwill D-210, Adwill D-203, Adwill D-202, Adwill D-175, and Adwill D-675 (all manufactured by LINTEC Corporation), SUMILITE [registered trade mark] FLS N8000 series (manufactured by Sumitomo Bakelite Co., Ltd.), and UC353EP-110 (manufactured by Furukawa Electric Co., Ltd.); or back grind tapes such as ELP RF-7232DB, ELP UB-5133D (both manufactured by Nitto Denko Corporation), SP-575B-150, SP-541B-205, SP-537T-160, and SP-537T-230 (all manufactured by FURUKAWA ELECTRIC Co., Ltd.) can be used.

A method of attaching the above-described film with a pressure-sensitive adhesive layer is not particularly limited, and the pressure-sensitive adhesive layer can be attached using a known surface protective tape attaching device and a laminator in the related art.

An average thickness hm of the adhesive layer 14 is preferably 10 μm or less, more preferably 5 μm or less, and still more preferably 1 μm or less. In a case where the average thickness hm of the adhesive layer 14 is 10 μm or less as described above, the protruding portion of the conduction path 22 can be protected, and a sufficient adhesive force can be exhibited with respect to the support 12.

The average thickness hm of the adhesive layer 14 is an average distance from the back surface 20b of the insulating base material 20.

The average thickness hm of the adhesive layer 14 is measured as follows. First, the adhesive layer 14 is cut in the thickness direction Dt of the anisotropically conductive member 16, and an image of the cut cross section is acquired with a field emission scanning electron microscope (FE-SEM). In the captured image, a distance from the back surface 20b of the insulating base material 20 corresponding to the adhesive layer is measured at 10 points, and an average value of lengths of the 10 measured points is obtained. The average value is defined as the average thickness hm of the adhesive layer 14.

### Insulating Base Material

The insulating base material 20 has electrical insulating properties and maintains a plurality of conduction paths 22, which are formed of a conductive substance, in a state of being electrically insulated from each other. The insulating base material 20 has a plurality of pores 21 in which the conduction path 22 is formed. A formulation and the like of the insulating base material will be described later.

A length of the insulating base material 20 in the thickness direction Dt, that is, a thickness ht of the insulating base material 20 is preferably in a range of 1 to 1,000 μm, more preferably in a range of 5 to 500 μm, still more preferably in a range of 10 to 300 μm, and particularly preferably 10 μm or more and 30 μm or less. In a case where the thickness of the insulating base material 20 is within the range, the handleability of the insulating base material 20 is improved.

The thickness of the insulating base material is measured as follows. First, the insulating base material is machined in the thickness direction Dt using a focused ion beam (FIB), and an image of a cross section thereof is acquired at a magnification of 50,000 times with a field emission scanning electron microscope (FE-SEM). In the captured image, lengths of 10 portions corresponding to the thickness of the insulating base material are measured, and an average value of the lengths of the 10 measured portions is obtained. The average value is defined as the thickness of the insulating base material.

The insulating base material 20 is not particularly limited as long as it consists of, for example, an inorganic material and has an electrical resistivity (approximately 10¹⁴ Ω·cm) similar to that of an insulating base material constituting the conventionally known anisotropic conductive film or the like.

The “consisting of an inorganic material” is a definition for distinguishing from a polymer material constituting a resin layer, which will be described later; and is not a definition limited to an insulating base material consisting of only an inorganic material, but is a definition in which an inorganic material is a main component (50% by mass or more).

Examples of the insulating base material include a metal oxide base material, a metal nitride base material, a glass base material, a ceramic base material such as silicon carbide and silicon nitride, a carbon base material such as diamond-like carbon, a polyimide base material, and a composite material thereof. In addition to the above, the insulating base material may be a film formed of an inorganic material containing 50% by mass or more of a ceramic material or a carbon material, on an organic material having through-holes.

In the insulating base material, micropores (pores) having a desired average opening diameter are formed as through-holes. From the viewpoint of easily forming the conduction path, the insulating base material is preferably a metal oxide base material and more preferably an anodized film of a valve metal.

Here, specific examples of the valve metal include aluminum, tantalum, niobium, titanium, hafnium, zirconium, zinc, tungsten, bismuth, and antimony. Among these, an aluminum anodized film (base material) is preferable since it has favorable dimensional stability and is relatively inexpensive. Accordingly, it is preferable to form an anodized film which is an insulating base material and to manufacture the anisotropically conductive member using an aluminum substrate.

A thickness of the anodized film is the thickness of the insulating base material 20 described above.

### Aluminum Substrate

The aluminum substrate for forming the anodized film which is an insulating base material is not particularly limited, and specific examples thereof include a pure aluminum plate; an alloy plate having aluminum as a main component and including a trace amount of foreign elements; a substrate obtained by vapor-depositing high-purity aluminum on low-purity aluminum (for example, a recycled material); a substrate obtained by covering a surface of a silicon wafer, quartz, glass, or the like with high-purity aluminum by a method such as vapor deposition and sputtering; and a resin substrate laminated with aluminum.

A surface of the aluminum substrate, on which the anodized film is provided by an anodization treatment step, preferably has an aluminum purity of 99.5% by mass or more, more preferably 99.9% by mass or more, and still more preferably 99.99% by mass or more. In a case where the aluminum purity is within the above-described range, regularity of the arrangement of the through-holes is sufficient. The micropores are pores.

The aluminum substrate is not particularly limited as long as the anodized film can be formed, and for example, Japanese Industrial Standards (JIS) 1050 Material is used.

In addition, it is preferable that the surface of the aluminum substrate on one side to be subjected to the anodization treatment step is subjected to a heat treatment, a degreasing treatment, and a mirror finishing treatment in advance.

Here, with regard to the heat treatment, the degreasing treatment, and the mirror finishing treatment, the same treatments as those described in paragraphs [0044] to [0054] of JP2008-270158A can be performed.

The mirror finishing treatment before the anodization treatment is, for example, electropolishing, and an electropolishing liquid containing phosphoric acid is used for the electropolishing.

### Average Diameter of Pores

An average diameter of the pores is preferably 1 μm or less, more preferably 5 to 500 nm, still more preferably 20 to 400 nm, even more preferably 40 to 200 nm, and most preferably 50 to 100 nm. In a case where the average diameter of the pores 21 is 1 μm or less and is within the above-described range, it is possible to obtain the conduction path 22 having the above-described average diameter.

The average diameter of the pores 21 is obtained by imaging the surface of the insulating base material 20 from directly above at a magnification of 100 to 10,000 times with a scanning electron microscope to obtain a captured image. At least 20 pores of which a periphery is connected in an annular shape are extracted from the captured image, diameters thereof are measured to obtain opening diameters, and an average value of the opening diameters is calculated as the average diameter of the pores.

For the magnification, a magnification in the above-described range can be appropriately selected so that the captured image from which 20 or more pores can be extracted is obtained. In addition, the opening diameter is measured as the maximum value of the distance between the end parts of the pore portions. That is, since the shape of the opening portion of the pores is not limited to the substantially circular shape, in a case where the shape of the opening portion is non-circular, the maximum value of the distance between the end parts of the pore portions is defined as the opening diameter. Therefore, for example, even in a case of pores having a shape in which two or more pores are integrated, the pores are regarded as one pore, and the maximum value of the distance between the end parts of the pore portions is regarded as the opening diameter.

### Conduction Path

The plurality of conduction paths 22 are provided in the insulating base material 20, for example, in the anodized film as described above in a state of being electrically insulated from each other.

Each of the plurality of conduction paths 22 is a columnar conductor having electrical conductivity, and is composed of a conductive substance. The conductive substance is not particularly limited, and examples thereof include a metal. Specific suitable examples of the metal include gold (Au), silver (Ag), copper (Cu), aluminum (Al), magnesium (Mg), nickel (Ni), zinc (Zn), and cobalt (Co). From the viewpoint of electrical conductivity, copper, gold, aluminum, nickel, or cobalt is preferable, copper or gold is more preferable, and copper is most preferable.

Since the metal is more excellent in ductility and the like and is easily deformed than the oxide conductor, and is easily deformed even in compression during bonding, it is preferable that the conductor is composed of a metal.

A height of the conduction path 22 in the thickness direction Dt is preferably 10 to 300 μm and more preferably 20 to 30 μm. The height of the conduction path 22 is a protrusion length ha of the protruding portion 22a+the thickness ht of the insulating base material 20+a protrusion length hb of the protruding portion 22b.

### Shape of Conduction Path

In the conduction path 22, the diameter Da on the front surface 20a of the insulating base material 20 and the diameter Db on the back surface 20b of the insulating base material 20 are different from each other. However, the average diameter of the conduction path 22 is preferably 1 μm or less, more preferably 10 nm or more and 500 nm or less, still more preferably 20 to 400 nm, even more preferably 40 to 200 nm, and most preferably 50 to 100 nm.

From the viewpoint of being able to be used as a test connector or the like of an electronic component such as a semiconductor element, a density of the conduction paths 22 on one surface and the other surface of the insulating base material 20, that is, a density of the conduction paths 22 on the front surface 20a and the back surface 20b of the insulating base material 20 is preferably 1×10⁶ to 1×10¹⁰/mm². The above-described density of the conduction paths 22 is more preferably 2×10⁶ to 8×10⁹/mm² and still more preferably 5×10⁶ to 5×10⁹/mm².

Furthermore, a center-to-center distance p of adjacent conduction paths 22 (see FIG. 1) is preferably 20 nm to 500 nm, more preferably 40 nm to 200 nm, and still more preferably 50 nm to 140 nm.

Regarding the conduction path 22, an interval w between adjacent protruding portions (see FIG. 1) is 20 nm to 200 nm, preferably 40 nm to 100 nm. In a case where the interval between the adjacent protruding portions adjacent is within the above-described range, the interval of the conduction path 22 can be maintained even on the front surface 20a or the back surface 20b of the insulating base material 20 of the conduction path 22. As a result, during the bonding, short-circuit of the conduction path 22 is suppressed, and thus reliability during the bonding is increased.

The diameter Da on the front surface 20a of the insulating base material 20 in the conduction path 22 and the diameter Db on the back surface 20b of the insulating base material 20 are each measured as follows.

First, the insulating base material 20 of the anisotropically conductive member 16 is machined in the thickness direction Dt using a focused ion beam, and an image of a cross section thereof is acquired at a magnification of 50,000 times with a field emission scanning electron microscope (FE-SEM). In the captured image, 10 portions corresponding to the conduction path 22 are selected, and in the selected 10 portions corresponding to the conduction path 22, lengths of the portions corresponding to the diameters Da and Db are measured. An average value of the lengths corresponding to the diameters Da of the 10 measured conduction paths 22 is obtained, and is defined as the diameter Da. In addition, an average value of the lengths corresponding to the diameters Db of the 10 measured conduction paths 22 is obtained, and is defined as the diameter Db.

In addition, the diameter Da of the conduction path 22 on the front surface 20a of the insulating base material 20 can be measured from a front surface image of the front surface 20a of the insulating base material 20 obtained by a field emission scanning electron microscope (FE-SEM). The diameter Db of the conduction path 22 on the back surface 20b of the insulating base material 20 can be measured from a back surface image of the back surface 20b of the insulating base material 20 obtained by a field emission scanning electron microscope (FE-SEM).

In a case where the front surface image and the back surface image are used as described above, and it is difficult to measure the diameter Da and the diameter Db due to the protruding portion, the protruding portion is removed by dissolution or the like. As a result, the pores appear. The opening diameter of the pores in the front surface image in this state can be measured, and the opening diameter of the pores in the front surface can be used instead of the diameter Da. In addition, similarly, the opening diameter of the pores in the back surface image in this state can be measured, and the opening diameter of the pores in the back surface can be used instead of the diameter Db.

The opening diameter of the above-described pores is measured as follows. First, 50 pieces of the pores are selected, and diameters of portions corresponding to the openings of the pores are measured for the 50 pieces of the pores. An average value of the diameters of the measured pores corresponding to the openings is calculated, and this average value is defined as the opening diameter of the pores.

The center-to-center distance p and interval w of adjacent conduction paths 22 are measured as follows. First, the front surface 20a of the insulating base material 20 is imaged from directly above at a magnification of 100 to 10,000 times with a scanning electron microscope to obtain a captured image. In the captured image of the insulating base material 20, the conduction path 22 to be measured is randomly selected. A center position (not shown) of the selected conduction path 22 is specified. A distance between center positions of the adjacent conduction paths is obtained at 10 locations. An average value thereof is defined as the center-to-center distance p of adjacent conduction paths 22. The center position is a center position of a region corresponding to the conduction path 22 in the above-described captured image. In the captured image, a known image analysis method can be used to calculate the center position of the region.

In addition, a distance corresponding to the interval w of the adjacent conduction paths in the selected conduction paths 22 is measured at 10 locations. An average value of lengths of the measured 10 positions is defined as the above-described interval w.

In addition, the magnification of any of the captured images can be appropriately selected in the above-described range so that the captured image from which 20 or more conduction paths 22 can be extracted is obtained.

In the conduction path 22, the protrusion length ha of the protruding portion 22a (see FIG. 1) and the protrusion length hb of the protruding portion 22b are preferably 10 nm to 1,000 nm and more preferably 50 nm to 500 nm. In a case where the protrusion length ha and the protrusion length hb are 10 nm to 1000 nm, bondability with a member to be bonded is improved.

The protrusion length ha is a protrusion amount of the conduction path 22 from the front surface 20a of the insulating base material 20. That is, the protrusion length ha is a length of the protruding portion 22a from the front surface 20a of the insulating base material 20.

The protrusion length hb is a protrusion amount of the conduction path 22 from the back surface 20b of the insulating base material 20. That is, the protrusion length hb is a length of the protruding portion 22b from the back surface 20b of the insulating base material 20.

For the protrusion length ha and the protrusion length hb, the insulating base material 20 is machined in the thickness direction Dt using a focused ion beam, and an image of a cross section thereof is acquired at a magnification of 50,000 times with a field emission scanning electron microscope (FE-SEM). In the captured image, 10 portions corresponding to the conduction path 22 are selected, and in the selected 10 portions corresponding to the conduction path 22, lengths of the portions corresponding to the length of the protruding portion 22a and the length of the protruding portion 22b are measured. An average value of the lengths of the 10 measured conduction paths 22 corresponding to the lengths of the protruding portions 22a is obtained, and defined as the length of the protruding portion 22a. In addition, an average value of the lengths corresponding to the lengths of the protruding portions 22b is obtained, and defined as the length of the protruding portion 22b.

### Resin Layer

The resin layer covers at least one surface of the front surface or the back surface of the insulating base material as described above, and protects the insulating base material and the conduction path. In a case where the conduction path has a protruding portion, the protruding portion is embedded in the resin layer. That is, the resin layer covers an end part of the conduction path which protrudes from the insulating base material, and protects the protruding portion.

In order to exhibit the above-described function, it is preferable that the resin layer exhibits fluidity in a temperature range of 50° C. to 200° C. and is cured at 200° C. or higher. The resin layer is, for example, a thermoplastic layer composed of a thermoplastic resin or the like, and the resin layer will be described in detail later.

An average thickness hj of the resin layer 18 is preferably 10 μm or less, more preferably 5 μm or less, and still more preferably 1 μm or less. In a case where the average thickness hj of the resin layer 18 is 10 μm or less as described above, the protruding portion of the conduction path 22 can be protected, and the effect of filling the periphery of the electrode during the bonding of the semiconductor device or the like can be sufficiently exhibited.

The average thickness hj of the resin layer 18 is an average distance from the front surface 20a of the insulating base material 20.

The average thickness hj of the resin layer 18 is measured as follows. First, the resin layer 18 is cut in the thickness direction Dt of the anisotropically conductive member 16, and an image of the cut cross section is acquired with a field emission scanning electron microscope (FE-SEM). In the captured image, a distance from the front surface 20a of the insulating base material 20 corresponding to the resin layer is measured at 10 points, and an average value of lengths of the 10 measured points is obtained. The average value is defined as the average thickness hj of the resin layer 18.

As the resin layer, a formulation shown below can also be used. Hereinafter, the formulation of the resin layer will be described. For example, the resin layer contains a polymer material, and may contain an antioxidant material.

Specific examples of a resin material constituting the resin layer include thermoplastic resins such as an ethylene-based copolymer, a polyamide resin, a polyester resin, a polyurethane resin, a polyolefin-based resin, an acrylic resin, an acrylonitrile-based resin, and a cellulose-based resin. As the resin material constituting the resin layer, polyacrylonitrile can also be used.

As the resin layer, in addition to the above, for example, a resin layer containing a main composition containing an acrylic polymer, an acrylic monomer, and a maleimide compound, which is described in WO2022/163260A, can be used.

From the viewpoint of transportability and viewpoint of ease of use as the anisotropically conductive member, the above-described resin layer is preferably a film with a peelable pressure-sensitive adhesive layer, which has weakened adhesiveness and can be peeled off by a heat treatment or an ultraviolet exposure treatment. As the film with a peelable pressure-sensitive adhesive layer, the same film as the above-described adhesive layer can be used.

As the resin layer, a formulation described in paragraphs [0110] to [0125] of JP2019-153415A can be further used.

### Another Example of Anisotropically Conductive Member

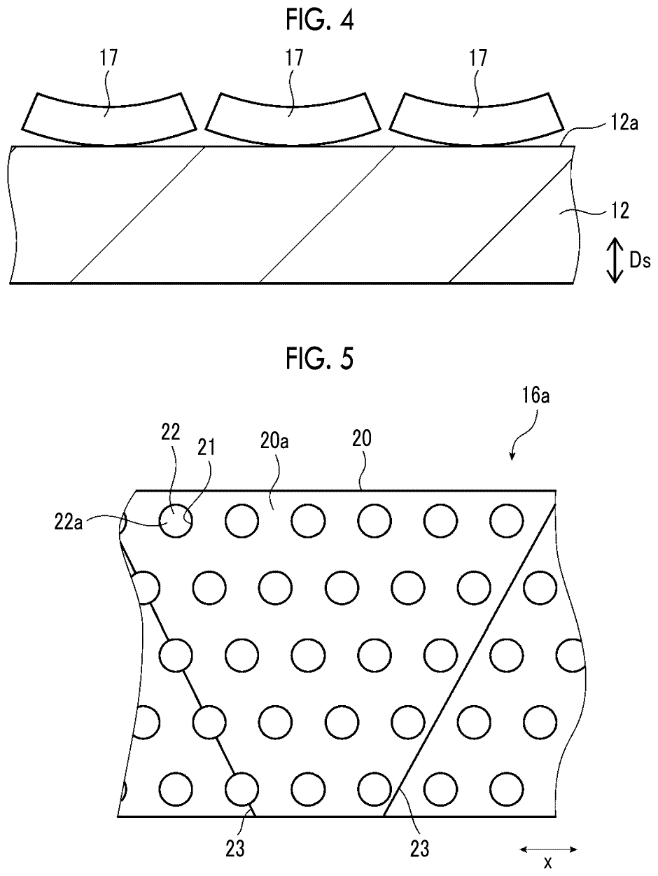

FIG. 5 is a schematic plan view showing another example of the anisotropically conductive member in the first example of the laminate according to the embodiment of the present invention. In FIG. 5, the same components as those of the laminate 10 shown in FIGS. 1 and 2 are designated by the same reference numerals, and detailed description thereof will not be repeated.

An anisotropically conductive member 16a shown in FIG. 5 is different from the anisotropically conductive member 16 shown in FIG. 1 in that the insulating base material 20 has cracks 23, but the other configurations are the same as those of the anisotropically conductive member 16 shown in FIG. 1. The anisotropically conductive member 16 may have the cracks 23. The anisotropically conductive member obtained by separating the anisotropically conductive member 16a shown in FIG. 5 into individual pieces also has the cracks 23.

The individualized anisotropically conductive member 17 (see FIG. 4) as described above warps, and in a case where the anisotropically conductive member is used as an electronic connection member, the anisotropically conductive member is in a flat state. In this case, distortion occurs in the anisotropically conductive member. The strain generated in the anisotropically conductive member is absorbed by the cracks 23. Therefore, in a case where deformability of the insulating base material 20 is small, the presence of the cracks 23 in the anisotropically conductive member 16a is effective.

In the anisotropically conductive member 16a, it is preferable that an average value of the total crack length per unit area in an electrode connection region connected to an electrode is 1 μm/mm² or less.

In addition, in the anisotropically conductive member 16a, it is preferable that an average value of the total crack length per unit area in an electrode non-connection region not connected to an electrode is 0.01 μm/mm² or more.

The electrode is an electrode to be connected, and is, for example, an electrode such as a semiconductor element and an interposer.

The above-described average value of the total crack length per unit area is a value in a state in which the anisotropically conductive member is separated into individual pieces. A method of measuring the average value of the total crack length per unit area will be described later. The crack refers to a crack having a length of 10 μm or more.

In the anisotropically conductive member 16a, in a case where the average value of the total crack length per unit area is 1 μm/mm² or less as described above in the electrode connection region connected to the electrode, conduction and electrical insulation are maintained.

Since it is preferable that there are no cracks in the electrode connection region, the lower limit of the average value of the total crack length per unit area in the electrode connection region is preferably close to zero and ideally zero.

In addition, in the anisotropically conductive member 16a, even in a case where the average value of the total crack length per unit area is 0.01 μm/mm² or more as described above in the electrode non-connection region not connected to the electrode, the conduction and the electrical insulation are maintained.

In a case where the average value of the total crack length in the electrode non-connection region is more than 1,000 μm/mm², the anisotropically conductive member tends to fall off or overlap, and thus the bonding properties deteriorate.

For example, there are the cracks 23 in the anisotropically conductive member 16a, but the amount of the cracks 23 is different between the electrode connection region connected to the electrode and the electrode non-connection region not connected to the electrode. It is preferable that the average value of the total crack length per unit area of the electrode connection region is smaller than the average value of the total crack length per unit area of the electrode non-connection region. In a case where the average value of the total crack length per unit area of the electrode connection region is smaller, the conductivity of the anisotropically conductive member 16a can be secured. In this case, the average value of the total crack length is relatively larger in the electrode non-connection region, and the number of the cracks 23 is large. In the anisotropically conductive member 16a, the conductivity is reduced due to the presence of the cracks 23, and as a result, the electrical insulation of the insulating base material 20 (see FIG. 1) in the direction x (see FIG. 1) is increased in the electrode non-connection region where the number of the cracks 23 is large. From this point, in a case where the individualized anisotropically conductive member is used as an electronic connection member, the conductivity and the electrical insulation are maintained.

As described above, the average value of the total crack length per unit area is a value in a state in which the anisotropically conductive member is separated into individual pieces. A method of measuring the average value of the total crack length per unit area will be described.

First, the anisotropically conductive member 16a is observed with an infrared microscope. Since the anisotropically conductive member 16a does not transmit infrared rays, the cracks 23 of the anisotropically conductive member 16a can be clearly detected by the infrared rays.

An inspection image of the entire plan view of the individualized anisotropically conductive member is acquired with an infrared microscope. A binarization process is performed on the acquired inspection image to obtain a binarized image of the inspection image. In black portions in the binarized image, those having a size of 10 μm or more correspond to the cracks. The length of the black portion of the binarized image is measured. As described above, since the cracks have a length of 10 μm or more, the cracks are extracted from the black portion with 10 μm as a threshold value. The total length of the extracted cracks is obtained. In addition, the area of the binarized image is obtained from the visual field area. The total crack length per unit area can be obtained from the crack length and the area of the binarized image. Next, the average value of the total crack length per unit area is obtained. In this way, the average value of the total crack length per unit area can be obtained.

### Second Example of Laminate

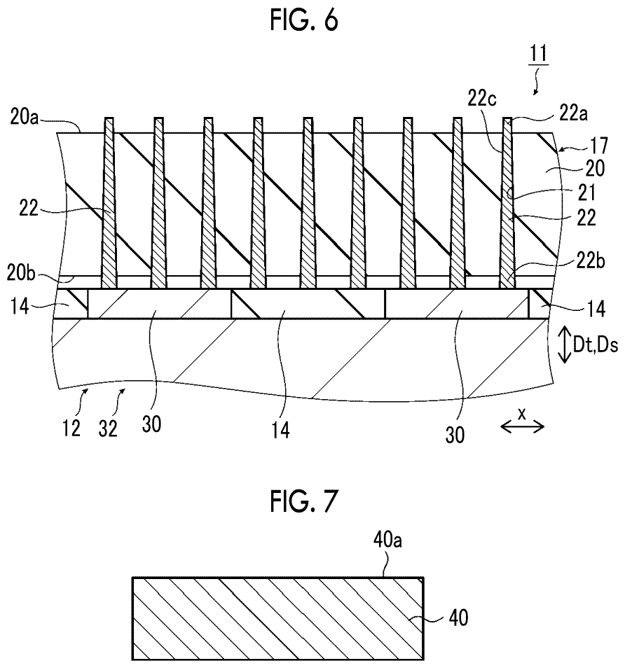

FIG. 6 is a schematic cross-sectional view showing a second example of the laminate according to the embodiment of the present invention. In FIG. 6, the same components as those of the laminate 10 shown in FIGS. 1 and 2 are designated by the same reference numerals, and detailed description thereof will not be repeated.

A laminate 11 shown in FIG. 6 is different from the laminate 10 shown in FIG. 1 in that the support 12 is a bonding member 32 having a metal layer 30 and the metal layer 30 is exposed from the adhesive layer 14; and the other configurations are the same as those of the laminate 10 shown in FIG. 1.

The support 12 can be bonded to the anisotropically conductive member 16 even in the configuration in which the support 12 is the bonding member 32 having the metal layer 30 exposed from the adhesive layer 14 and the bonding area with the anisotropically conductive member 16 is small, and warping occurs. Therefore, in a case where the individualized anisotropically conductive member is used as the electronic connection member, an object to be connected is an electrode corresponding to the metal layer 30, and the resin layer corresponds to the adhesive layer 14, the resin layer corresponding to the adhesive layer 14 absorbs the warping of the individualized anisotropically conductive member, which makes it possible to be suitably bonded to the object to be connected.

### Object to be Connected to Anisotropically Conductive Member

In a case where the anisotropically conductive member is used as the electronic connection member, an object to be connected is, for example, a semiconductor element, or an element having an electrode or an element region. Examples of the element having an electrode include a semiconductor element which exhibits a specific function by itself, but also include a case in which a plurality of elements are gathered to exhibit the specific function. Furthermore, it also includes a wiring member which only transmit electrical signals, and also includes a printed wiring board or the like which has an electrode.

The element region is a region in which various element configuration circuits and the like, for functioning as an electronic element, are formed. The element region includes, for example, a region where a memory circuit of a flash memory or the like, and a logic circuit such as a microprocessor, a field-programmable gate array (FPGA), or the like are formed and a region where a communication module such as a wireless tag, and a wiring line are formed. In addition to the above, a micro electro mechanical system (MEMS) may be formed in the element region. Examples of the MEMS include a sensor, an actuator, and an antenna. The sensor includes, for example, various sensors for acceleration, sound, light, and the like. The optical sensor is not particularly limited as long as it can detect light, and for example, a charge coupled device (CCD) image sensor or a complementary metal oxide semiconductor (CMOS) image sensor is used.

As described above, an element region is formed with an element configuration circuit or the like, and an electrode (not shown) is provided to electrically connect the semiconductor chip to the outside. The element region has an electrode region in which an electrode is formed. The electrode of the element region is, for example, a Cu post. The electrode region is basically a region including all formed electrodes. However, in a case where the electrodes are provided discretely, the region where each electrode is provided is also referred to as the electrode region.

A form of the object to be connected may be a form of a single piece such as a semiconductor chip, a form such as a semiconductor wafer, or a form of a wiring layer.

In addition, the anisotropically conductive member is bonded to the object to be connected, but the object to be connected is not particularly limited to the above-described semiconductor element and the like; and for example, a semiconductor element in a wafer state, a semiconductor element in a chip state, a printed wiring board, a heat sink, or the like can be used as the object to be connected.

### Semiconductor Element

In addition to the above, examples of the semiconductor element include a logic large scale integration (logic LSI) (for example, an application specific integrated circuit (ASIC), a field programmable gate array (FPGA), or an application specific standard product (ASSP)), a microprocessor (for example, a central processing unit (CPU) or a graphics processing unit (GPU)), a memory (for example, a dynamic random access memory (DRAM), a hybrid memory cube (HMC), a magnetic memory (magnetic RAM; MRAM), a phase-change memory (PCM), a resistive memory (resistive RAM; ReRAM), a ferroelectric RAM (FeRAM: a ferroelectric memory), or flash memory (not AND (NAND) flash)), a light emitting diode (LED) (for example, a micro flash of a mobile terminal, in-vehicle use, a projector light source, an LCD backlight, or general lighting use), a power device, analog integrated circuit (IC), (for example, a direct current (DC)-direct current (DC) converter, or an insulated gate bipolar transistor (IGBT)), micro electro mechanical systems (MEMS), (for example, an acceleration sensor, a pressure sensor, an oscillator, or a gyro sensor), wireless (for example, a global positioning system (GPS), a frequency modulation (FM), a near field communication (NFC), an RF expansion module (RFEM), a monolithic microwave integrated circuit (MMIC), or a wireless local area network (WLAN)), and a discrete element, back side Illumination (BSI), a contact image sensor (CIS), a camera module, a complementary metal oxide semiconductor (CMOS), a passive device, a surface acoustic wave (SAW) filter, a radio frequency (RF) filter, a radio frequency integrated passive device (RFIPD), and broadband (BB).

The semiconductor element is, for example, one complete unit, and the semiconductor element alone exhibits a specific function such as a circuit and a sensor. The semiconductor element may have an interposer function. In addition, for example, it is possible to stack a plurality of devices such as a logic chip having a logic circuit and a memory chip on a device having an interposer function. Furthermore, in this case, even in a case where the electrode size is different for each device, the bonding can be carried out.

### Example of Method for Manufacturing Laminate

Next, a method for manufacturing the laminate will be described. FIGS. 7 to 15 are schematic cross-sectional views showing an example of the method for manufacturing the laminate according to the embodiment of the present invention in the order of steps. In FIGS. 7 to 15, components having the same constitution as that of the laminate 10 shown in FIGS. 1 and 2 are designated by the same reference numerals, and detailed description thereof will not be repeated.

In one example of the method for manufacturing the laminate, the anisotropically conductive member 16 of the laminate 10 shown in FIG. 1 will be described with a configuration in which the insulating base material 20 is an aluminum anodized film. An aluminum substrate is used for forming the aluminum anodized film. Therefore, in the example of the method for manufacturing the laminate, first, an aluminum substrate 40 is prepared as shown in FIG. 7.

The size and the thickness of the aluminum substrate 40 are appropriately determined depending on the thickness of the insulating base material 20 (see FIG. 1) in the finally obtained anisotropically conductive member 16 (see FIG. 1), a device for processing, and the like. The aluminum substrate 40 is, for example, a plate material having a circular outer shape. The substrate is not limited to the aluminum substrate, and a metal substrate capable of forming an electrically insulating film can be used. A valve metal capable of forming an anodized film by anodization can be used.

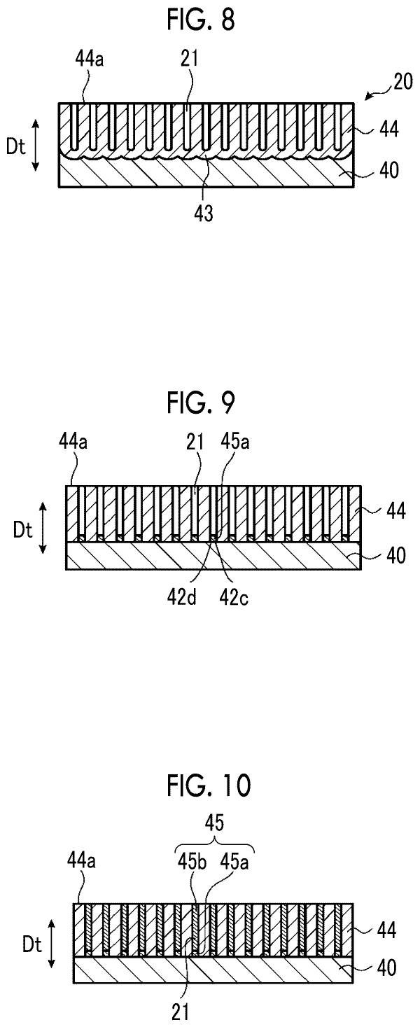

Next, one surface 40a (see FIG. 7) of the aluminum substrate 40 is subjected to an anodization treatment. As a result, one surface 40a (see FIG. 7) of the aluminum substrate 40 is anodized, and as shown in FIG. 8, an anodized film 44 having a plurality of pores 21 extending in the thickness direction Dt of the aluminum substrate 40 is formed. The pores 21 of the anodized film 44 have a larger diameter on a front surface 44a side of the anodized film 44 than on the aluminum substrate 40 side.

The anodized film 44 is the above-described insulating base material 20 (see FIG. 1). As shown in FIG. 8, a barrier layer 43 is present at a bottom portion of each pore 21. The above-described anodizing step is referred to as an anodization treatment step.

In the anodized film 44 having the plurality of pores 21, the barrier layer 43 is present at the bottom portion of each pore 21 as described above, and the barrier layer 43 is removed. In this manner, an anodized film 44 (see FIG. 9) having a plurality of pores 21 and no barrier layer 43 is obtained. The above-described step of removing the barrier layer 43 is referred to as a barrier layer removing step.

In the barrier layer removing step, by using an alkaline aqueous solution containing ions of a metal M1 having a higher hydrogen overvoltage than aluminum, the barrier layer 43 of the anodized film 44 is removed, and at the same time, a metal layer 45a (see FIG. 10) consisting of a metal (metal M1) is formed on a surface 42d (see FIG. 9) of a bottom portion 42c (see FIG. 9) of the pores 21. As a result, the aluminum substrate 40 exposed to the pores 21 is coated with the metal layer 45a. In this manner, in a case where the pores 21 are filled with a metal by plating, the plating is likely to proceed and the insufficient filling of the pores 21 with a metal is suppressed, and thus the formation of the conduction path 22 (see FIG. 1) is suppressed.

The above-described alkali aqueous solution containing the ions of the metal M1 may further contain an aluminum ion-containing compound (such as sodium aluminate, aluminum hydroxide, and aluminum oxide). A content of the aluminum ion-containing compound is preferably 0.1 to 20 g/L, more preferably 0.3 to 12 g/L, and still more preferably 0.5 to 6 g/L in terms of the amount of aluminum ions.

Next, the plating is performed from the front surface 44a of the anodized film 44 having a plurality of the pores 21 extending in the thickness direction Dt. In this case, the metal layer 45a can be used as an electrode for the electrolytic plating. In the plating, a metal 45b is used, and the plating proceeds starting from the metal layer 45a formed on the surface 42d (see FIG. 9) of the bottom portion 42c (see FIG. 9) of the pores 21. As a result, as shown in FIG. 10, the inside of the pores 21 of the anodized film 44 is filled with the metal 45b as the conductive substance constituting the conduction path 22. By filling the inside of the pores 21 with the metal 45b, the conduction path 22 having conductivity is formed. The metal layer 45a and the metal 45b are collectively referred to as a metal 45.

The step of filling the plurality of pores 21 of the anodized film 44 with the metal 45b to form the plurality of conduction paths 22 is referred to as a metal filling step. As described above, the conduction path 22 is composed of the conductive substance, and is not limited to being filled with the metal. The electrolytic plating is used in the metal filling step, and the metal filling step will be described in detail later. The front surface 44a of the anodized film 44 corresponds to one surface of the insulating base material 20. The step of filling the plurality of the pores 21 of the anodized film 44 with a conductive substance containing a metal and a substance other than the metal to form the plurality of conduction paths 22 is simply referred to as a filling step.

After the metal filling step, a polishing step of polishing and smoothing the front surface 44a of the anodized film 44 shown in FIG. 10 is performed. For the polishing, for example, a chemical mechanical polishing (CMP) treatment is used.

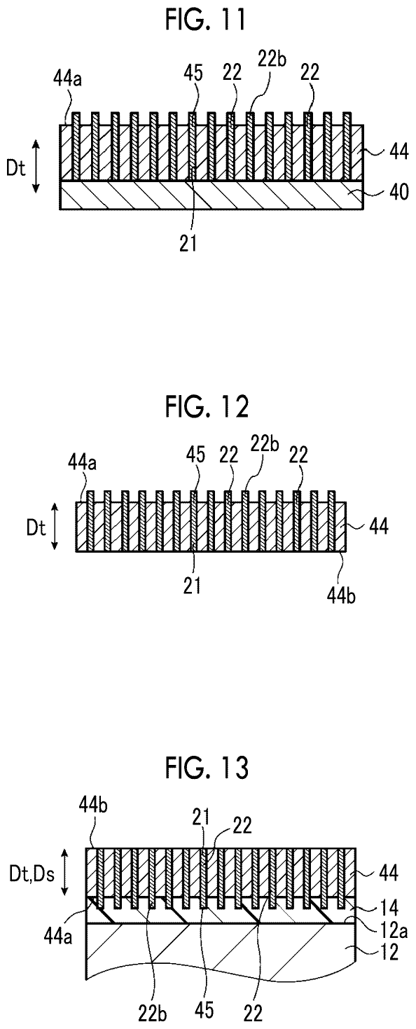

Next, after the polishing step, as shown in FIG. 11, the front surface 44a of the anodized film 44 on the side where the aluminum substrate 40 is not provided is partially removed in the thickness direction Dt, and the metal 45 filled in the metal filling step protrudes from the front surface 44a of the anodized film 44. That is, the conduction path 22 is allowed to protrude from the front surface 44a of the anodized film 44. As a result, the protruding portion 22b is obtained. The step of causing the conduction path 22 to protrude from the front surface 44a of the anodized film 44 is referred to as a front surface protruding step. The front surface protruding step does not necessarily need to be performed. In a case where the front surface protruding step is not performed, the above-described protruding portion 22b is not formed.

After the front surface protruding step, the aluminum substrate 40 is removed as shown in FIG. 12. The step of removing the aluminum substrate 40 is referred to as a substrate removing step.

Next, as shown in FIG. 13, the front surface 44a of the anodized film 44 is directed toward the surface 12a of the support 12, and the anodized film 44 and the support 12 are adhered to each other using the adhesive layer 14. In this case, for example, after a film with a pressure-sensitive adhesive layer is attached to the surface 12a of the support 12 as the adhesive layer 14, the front surface 44a of the anodized film 44 is attached to the film with a pressure-sensitive adhesive layer with facing the surface 12a of the support 12. The step of attaching the anodized film 44 to the support 12 using the above-described adhesive layer 14 is referred to as a support forming step.

After the support forming step, a polishing step of polishing and smoothing a back surface 44b of the anodized film 44 is performed. For the polishing, for example, a CMP treatment is used.

Here, as described above, the pores 21 have a larger diameter on the front surface 44a side of the anodized film 44 than on the aluminum substrate 40 side, and the diameter of the pores 21 on the front surface 44a of the anodized film 44 is different from the diameter of the pores 21 on the back surface 44b of the anodized film 44. In the anodized film 44, the diameter of the pores 21 is larger on the front surface 44a side than on the back surface 44b side. From this point, the diameter of the conduction path 22 is different between the front surface 44a of the anodized film 44 and the back surface 44b of the anodized film 44, and the diameter of the conduction path 22 is larger on the front surface 44a side of the anodized film 44.

The front surface 44a of the anodized film 44 corresponds to the back surface 20b of the insulating base material 20, and the back surface 44b of the anodized film 44 corresponds to the front surface 20a of the insulating base material 20. Therefore, the diameter of the conduction path 22 can be adjusted by adjusting a polishing amount of the front surface 44a of the anodized film 44 or the back surface 44b of the anodized film 44. For example, the above-described ratio of the diameter Da and the diameter Db can be adjusted by adjusting the polishing amount of the back surface 44b of the anodized film 44. In addition, the adjustment of the above-described ratio of the diameter Da and the diameter Db can also be achieved by adjusting the polishing amount of the front surface 44a of the anodized film 44 and the polishing amount of the back surface 44b of the anodized film 44. The polishing amount can be adjusted, for example, by adjusting a polishing time.

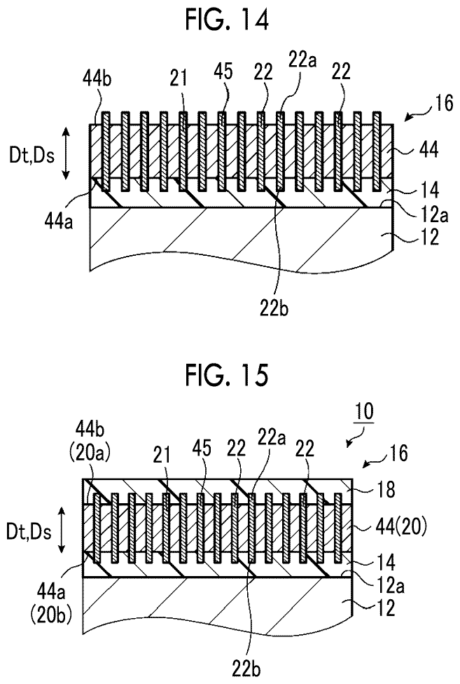

Next, after the polishing step of the back surface 44b of the anodized film 44, as shown in FIG. 14, a part of the back surface 44b of the anodized film 44 is removed in the thickness direction Dt, and the metal 45 filled in the metal filling step, that is, the conduction path 22 is made to protrude from the back surface 44b of the anodized film 44. As a result, the protruding portion 22a is obtained, thereby forming the anisotropically conductive member 16.

As shown in FIG. 14, the conduction path 22 protrudes from each of the front surface 44a and the back surface 44b of the anodized film 44, and the conduction path 22 has the protruding portion 22a and the protruding portion 22b.

The step of causing the conduction path 22 to protrude from the back surface 44b of the anodized film 44 is referred to as a back surface protruding step. The back surface protruding step does not necessarily need to be performed. In a case where the back surface protruding step is not performed, the above-described protruding portion 22a is not formed.

The above-described front surface protruding step and back surface protruding step may have an aspect in which both steps are performed, or may have an aspect in which one of the front surface protruding step or the back surface protruding step is performed. The front surface protruding step and the back surface protruding step correspond to the “protruding step”, and both the front surface protruding step and the back surface protruding step are the protruding step. The protruding step is also referred to as a trimming step.

In a case where the protruding step is performed, the thickness of the anodized film 44 after the protruding step is the thickness of the insulating base material.

Next, as shown in FIG. 15, the resin layer 18 covering the entire back surface 44b of the anodized film 44, from which the protruding portion 22a protrudes, is formed. In this manner, the laminate 10 is manufactured. The resin layer 18 can be formed, for example, in the same manner as the above-described adhesive layer 14.

### Anodization Treatment Step

As the anodization treatment, a known method in the related art can be used, but from the viewpoint of increasing the regularity of the micropore arrangement and ensuring the anisotropic conductivity of the anisotropically conductive member, it is preferable to use a self-regulation method or a constant voltage treatment. As a result, for example, the pores and the conduction paths are arranged in a hexagonal shape.

Here, with regard to the self-regulation method or the constant voltage treatment for the anodization treatment, the same treatments as those described in paragraphs [0056] to [0108] and [FIG. 8] of JP2008-270158A can be performed.

### Holding Step

In a case of manufacturing the anisotropically conductive member, a holding step may be provided. The holding step is a step of holding a voltage of 95% or more and 105% or less of the holding voltage selected from the range of 1 V or more and less than 30% of the voltage in the above-described anodization treatment step for a total of 5 minutes or more, after the above-described anodization treatment step. In other words, the holding step is a step of performing, after the above-described anodization treatment step, an electrolytic treatment at a voltage of 95% or more and 105% or less of the holding voltage selected from the range of 1 V or more and less than 30% of the voltage in the above-described anodization treatment step for a total of 5 minutes or more.

Here, the “voltage in the anodization treatment” is a voltage applied between the aluminum substrate and the counter electrode; and for example, in a case where the electrolysis time by the anodization treatment is 30 minutes, the “voltage in the anodization treatment” refers to an average value of the voltage maintained for 30 minutes.

From the viewpoint of controlling the thickness of the side wall of the anodized film, that is, the thickness of the barrier layer with respect to the depth of the pores to a proper thickness, the voltage in the holding step is preferably 5% or more and 25% or less and more preferably 5% or more and 20% or less of the voltage in the anodization treatment.

In addition, from the reason that in-plane uniformity is further improved, the total holding time in the holding step is preferably 5 minutes or more and 20 minutes or less, more preferably 5 minutes or more and 15 minutes or less, and still more preferably 5 minutes or more and 10 minutes or less.

In addition, the holding time in the holding step may be a total of 5 minutes or more, but is preferably 5 minutes or more continuously.

Furthermore, the voltage in the holding step may be set to be continuously or stepwise lowered from the voltage in the anodization treatment step to the voltage in the holding step, but from the reason that the in-plane uniformity is further improved, it is preferable to set the voltage to 95% or more and 105% or less of the above-described holding voltage within 1 second after the completion of the anodization treatment step.

The above-described holding step can be performed continuously together with the above-described anodization treatment step by, for example, lowering the electrolytic potential at the end part of the above-described anodization treatment step.

In the above-described holding step, the same electrolytic solution and treatment conditions as those of the above-described conventionally known anodization treatment can be adopted except for the electrolytic potential conditions.

In particular, in a case where the holding step and the anodization treatment step are continuously performed, it is preferable to perform the treatments using the same electrolytic solution.

In the anodized film having a plurality of pores (micropores), the barrier layer (not shown) is present at the bottom portion of the pores as described above. The barrier layer removing step of removing the barrier layer is provided.

### Barrier Layer Removing Step

The barrier layer removing step is a step of removing the barrier layer of the anodized film by using, for example, an alkaline aqueous solution containing ions of a metal M1 having a higher hydrogen overvoltage than aluminum.

By the above-described barrier layer removing step, the barrier layer is removed, and a conductor layer consisting of the metal M1 is formed at the bottom portion of the pores.

Here, the hydrogen overvoltage means a voltage required for hydrogen to be generated; and for example, a hydrogen overvoltage of aluminum (Al) is −1.66 V (Journal of the Chemical Society of Japan, 1982, (8), pp. 1305 to 1313). Examples of the metal M1 having a higher hydrogen overvoltage than aluminum and the value of the hydrogen overvoltage thereof are shown below.

### Metal M1 and Hydrogen (1N H₂SO₄) Overvoltage

Platinum (Pt): 0.00 V
Gold (Au): 0.02 V
Silver (Ag): 0.08 V
Nickel (Ni): 0.21 V
Copper (Cu): 0.23 V
Tin (Sn): 0.53 V
Zinc (Zn): 0.70 V

In the above-described barrier layer removing step, by removing the barrier layer using the alkaline aqueous solution containing ions of the metal M1 having a higher hydrogen overvoltage than aluminum, not only the barrier layer 43 is removed, but also the metal layer 45a of the metal M1, which is less likely to generate hydrogen gas than aluminum, is formed on the aluminum substrate 40 exposed at the bottom portion of the pores 21. As a result, the in-plane uniformity of the metal filling is favorable. It is presumed that the generation of hydrogen gas by the plating liquid is suppressed and thus the metal filling by the electrolytic plating proceeds easily.

In addition, in the barrier layer removing step, in a case where the holding step of holding the voltage of 95% or more and 105% or less of the voltage (the holding voltage) selected from a range of less than 30% of the voltage in the anodization treatment step for a total of 5 minutes or more is provided and the application of the alkali aqueous solution containing ions of the metal M1 is combined, it has been found that the uniformity of the metal filling during the plating treatment is greatly improved. Therefore, it is preferable that the holding step is provided.

Although the detailed mechanism is unknown, it is presumed that, in the barrier layer removing step, a layer of the metal M1 is formed in the lower part of the barrier layer by using the alkali aqueous solution containing ions of the metal M1, whereby damage of an interface between the aluminum substrate and the anodized film can be suppressed, and thus the uniformity of the dissolution of the barrier layer is improved.

In the barrier layer removing step, although the metal layer 45a consisting of a metal (metal M1) is formed at the bottom portion of the pores 21, the present invention is not limited thereto, and only the barrier layer 43 is removed to expose the aluminum substrate 40 at the bottom of the pores 21. The aluminum substrate 40 may be used as an electrode for electrolytic plating in a state in which the aluminum substrate 40 is exposed.

The pores 21 can also be formed by widening the diameter of the micropores and removing the barrier layer. In this case, a pore widening treatment is used for the diameter widening of the micropores. The pore widening treatment is a treatment of dissolving the anodized film by immersing the anodized film in an acid aqueous solution or an alkali aqueous solution to enlarge the pore diameter of the micropores. In the pore widening treatment, an aqueous solution of an inorganic acid such as sulfuric acid, phosphoric acid, nitric acid, and hydrochloric acid, or a mixture thereof, or an aqueous solution of sodium hydroxide, potassium hydroxide, lithium hydroxide, or the like can be used.

In the pore widening treatment, the barrier layer at the bottom portion of the micropores can also be removed, and the micropores are enlarged and the barrier layer is removed by using a sodium hydroxide aqueous solution in the pore widening treatment.

### Filling Step

The filling step is a step of filling the pores of the anodized film having a plurality of pores extending in the thickness direction, that is, the insulating base material, with a conductive substance to form a plurality of conduction paths. The conduction path is, for example, a columnar conductor. In a case where the metal is filled as the conductive substance in the filling step, it is referred to as a metal filling step.

### Metal Used in Filling Step

In the filling step, it is preferable that the metal filled as the conductive substance inside the pores 21 of the anodized film 44 described above in order to form the conduction path is a material having an electrical resistivity of 10³ Ω·cm or less. Specific suitable examples of the above-described metal include gold (Au), silver (Ag), copper (Cu), aluminum (Al), magnesium (Mg), nickel (Ni), zinc (Zn), and cobalt (Co).

From the viewpoint of electrical conductivity and formation by a plating method, as the conductive substance, copper (Cu), gold (Au), aluminum (Al), nickel (Ni), or cobalt (Co) is preferable, copper (Cu) or gold (Au) is more preferable, and copper (Cu) is still more preferable.

### Plating Method

As a plating method of filling the inside of the pores 21 with the metal for the anodized film 44 having the plurality of pores 21 extending in the thickness direction Dt, for example, an electrolytic plating method or an electroless plating method can be used.

Here, it is difficult to selectively precipitate (grow) the metal in a hole with a high aspect ratio by an electrolytic plating method known in the related art, which is used for coloration and the like. This is presumed to be because the precipitated metal is consumed in the hole, and thus the plating does not proceed even in a case where electrolysis is carried out for a constant period time or longer.

Therefore, in a case where the metal is filled by the electrolytic plating method, it is necessary to provide a rest time during pulse electrolysis or constant potential electrolysis. A rest time of 10 seconds or longer is required, and the rest time is preferably 30 to 60 seconds.

In addition, it is also desirable to apply ultrasonic waves to promote stirring of the electrolytic solution.

Furthermore, an electrolytic voltage is usually 20 V or less, desirably 10 V or less, but it is preferable that a precipitation potential of a target metal in the electrolytic solution to be used in advance is measured and constant potential electrolysis is performed within the potential+1 V. In a case of performing the constant potential electrolysis, it is desirable that cyclic voltammetry can be used in combination, and a potentiostat device from Solartron Analytical, BAS Inc., HOKUTO DENKO Corporation, IVIUM Technologies B. V., or the like can be used.

### Plating Liquid

As a plating liquid, a plating liquid known in the related art can be used.

Specifically, a copper sulfate aqueous solution is generally used for precipitating copper, and a concentration of copper sulfate is preferably 1 to 300 g/L and more preferably 100 to 200 g/L. In addition, the precipitation can be promoted by adding hydrochloric acid to the electrolytic solution. In this case, a concentration of hydrochloric acid is preferably 10 to 20 g/L.

In addition, in a case of precipitating gold, it is desirable that a sulfuric acid solution of tetrachloroaurate is used and the plating is performed by alternating current electrolysis.

The plating liquid preferably contains a surfactant.

As the surfactant, a known surfactant can be used. Sodium lauryl sulfate, which is known as a surfactant added to the plating liquid in the related art, can also be used as it is. Both ionic (cationic, anionic, or zwitterionic) and nonionic hydrophilic moieties can be used, but a cationic surfactant is desirable from the viewpoint of avoiding the generation of bubbles on the surface of the plating target object. A concentration of the surfactant in the formulation of the plating liquid is desirably 1% by mass or less.

In the electroless plating method, it takes a long time to completely fill the pores consisting of pores having a high aspect ratio with the metal, and thus it is desirable to fill the pores with a metal by the electrolytic plating method.

### Substrate Removing Step

The substrate removing step is a step of removing the above-described aluminum substrate after the filling step. The method of removing the aluminum substrate is not particularly limited, and suitable examples thereof include a method of removing the aluminum substrate by dissolution.

### Dissolution of Aluminum Substrate

For the above-described dissolution of the aluminum substrate, it is preferable to use a treatment liquid in which the anodized film is difficult to be dissolved but the aluminum is easily dissolved.

In such a treatment liquid, a dissolution rate for the aluminum is preferably 1 μm/min or more, more preferably 3 μm/min or more, and still more preferably 5 μm/min or more. In addition, a dissolution rate for the anodized film is preferably 0.1 nm/min or less, more preferably 0.05 nm/min or less, and still more preferably 0.01 nm/min or less.

Specifically, the treatment liquid is preferably a treatment liquid containing at least one metal compound having an ionization tendency lower than that of aluminum and having a pH of 4 or less or 8 or more. The pH of the treatment liquid is more preferably 3 or less or 9 or more, and still more preferably 2 or less or 10 or more.

The treatment liquid for dissolving the aluminum is preferably a treatment liquid obtained by formulating, for example, a compound of manganese, zinc, chromium, iron, cadmium, cobalt, nickel, tin, lead, antimony, bismuth, copper, mercury, silver, palladium, platinum, or gold (for example, chloroplatinic acid), fluorides of these metals, and chlorides of these metals, based on an acid or alkali aqueous solution.

Among these, an acid aqueous solution-based treatment liquid is preferable, and a chloride-blended treatment liquid is preferable.

In particular, from the viewpoint of treatment latitude, a treatment liquid obtained by blending mercury chloride with a hydrochloric acid aqueous solution (hydrochloric acid/mercuric chloride) or a treatment liquid obtained by blending copper chloride with a hydrochloric acid aqueous solution (hydrochloric acid/copper chloride) is preferable.

The formulation of the treatment liquid for dissolving the aluminum is not particularly limited, and for example, a bromine/methanol mixture, a bromine/ethanol mixture, aqua regia, or the like can be used.

In addition, a concentration of acid or alkali of the treatment liquid for dissolving the aluminum is preferably 0.01 to 10 mol/L and more preferably 0.05 to 5 mol/L.

Furthermore, a treatment temperature in a case of using the treatment liquid for dissolving the aluminum is preferably −10° C. to 80° C. and more preferably 0° C. to 60° C.

In addition, the above-described dissolution of the aluminum substrate is carried out by bringing the aluminum substrate after the above-described plating step into contact with the above-described treatment liquid. A contact method is not particularly limited, and examples thereof include a dipping method and a spraying method. Among these, a dipping method is preferable. A contact time in this case is preferably 10 seconds to 5 hours, and more preferably 1 minute to 3 hours.

In addition, for example, a support base material may be provided in the anodized film 44 in a case of forming the anisotropically conductive member. The support base material preferably has the same outer shape as the anodized film 44. In a case where the support base material is attached, the handleability of the anodized film 44 is improved in a case of forming the anisotropically conductive member.

### Protruding Step

The protruding step is a step of causing the conduction path to protrude from at least one of one surface or the other surface of the insulating base material after the polishing step.

Specific examples thereof include removing a part of the above-described anodized film 44. For the removal of a part of the anodized film 44, for example, an acid aqueous solution or an alkali aqueous solution, which does not dissolve the metal constituting the conduction path 22 but dissolves the anodized film 44, that is, aluminum oxide (Al₂O₃), is used. The anodized film 44 is partially removed by bringing the above-described acid aqueous solution or alkali aqueous solution into contact with the anodized film 44 having the pores 21 filled with the metal. The method of bringing the above-described acid aqueous solution or alkali aqueous solution into contact with the anodized film 44 is not particularly limited, and examples thereof include a dipping method and a spraying method. Among these, a dipping method is preferable.

In a case where the acid aqueous solution is used, it is preferable to use an aqueous solution of an inorganic acid such as sulfuric acid, phosphoric acid, nitric acid, and hydrochloric acid, or a mixture thereof. Among these, an aqueous solution containing no chromic acid is preferable since it is excellent in safety. A concentration of the acid aqueous solution is preferably 1% to 10% by mass. A temperature of the acid aqueous solution is preferably 25° C. to 60° C.

In addition, in a case where the alkali aqueous solution is used, it is preferable to use at least one alkali aqueous solution selected from the group consisting of sodium hydroxide, potassium hydroxide, and lithium hydroxide. A concentration of the alkali aqueous solution is preferably 0.1% to 5% by mass. A temperature of the alkali aqueous solution is preferably 20° C. to 35° C.

Specifically, for example, a phosphoric acid aqueous solution of 50 g/L and 40° C., a sodium hydroxide aqueous solution of 0.5 g/L and 30° C., or a potassium hydroxide aqueous solution of 0.5 g/L and 30° C. is suitably used.

A dipping time in the acid aqueous solution or the alkali aqueous solution is preferably 8 to 120 minutes, more preferably 10 to 90 minutes, and still more preferably 15 to 60 minutes. Here, the dipping time means the total of each of dipping times in a case where a dipping treatment for a short time is repeated. A washing treatment may be carried out between the dipping treatments.

In addition, the metal 45, that is, the conduction path 22 is allowed to protrude from the front surface 44a or the back surface 44b of the anodized film 44 to a certain extent; but it is preferable that the conduction path 22 protrudes from the front surface 44a or the back surface 44b of the anodized film 44 by 10 nm to 1,000 nm as described above. That is, the protrusion length ha of the protruding portion 22a from the back surface 44b and the protrusion length hb of the protruding portion 22b from the front surface 44a of the conduction path 22 are each preferably 10 nm to 1,000 nm and more preferably 50 nm to 500 nm, since the bondability with a member to be bonded is improved.

In a case where the protrusion lengths ha and hb of the protruding portions of the conduction path 22 are strictly controlled, it is preferable that the inside of the pores 21 is filled with a conductive substance such as a metal, the anodized film 44 and the end part of the conductive substance such as a metal are processed to have the same planar shape, and then the insulating base material such as the anodized film is selectively removed.

In addition, after the filling of the metal or after the protruding step, a heat treatment can be performed for the purpose of reducing the distortion in the conduction path 22 generated in association with the filling of the metal.

From the viewpoint of suppressing oxidation of the metal, the heat treatment is preferably performed in a reducing atmosphere; and specifically, the heat treatment is preferably performed at an oxygen concentration of 20 Pa or less, and more preferably performed under vacuum. Here, the vacuum refers to a state of a space in which at least one of a gas density or an atmospheric pressure is lower than that of the atmosphere.

In addition, it is preferable that the heat treatment is performed while applying a stress to the anodized film 44 for the purpose of correction.

### Resin Layer Forming Step

In the step of forming the resin layer 18, for example, an ink jet method, a transfer method, a spraying method, a screen printing method, or the like is used. The ink jet method is preferable since the step of forming the resin layer 18 can be simplified, because the resin layer 18 is directly formed on the insulating base material 20. In addition, the resin layer 18 can be formed using, for example, a known surface protective tape attaching device and a laminator in the related art. In addition, in the step of forming the resin layer, the resin layer is formed on the entire surface of the insulating base material. A resin material constituting the resin layer 18 is as described above.

Examples of the method of forming the resin layer 18 include a method of applying a resin composition containing an antioxidant material, a polymer material, a solvent (for example, methyl ethyl ketone), and the like described later onto the entire surface of the insulating base material, drying the resin composition, and baking the resin composition as necessary, in addition to the above-described method.

A method for applying the resin composition is not particularly limited, and for example, known coating method in the related art, such as a gravure coating method, a reverse coating method, a die coating method, a blade coating method, a roll coating method, an air knife coating method, a screen coating method, a bar coating method, and a curtain coating method, can be used.

In addition, a drying method after the applying is not particularly limited, and examples thereof include a heat treatment at a temperature of 0° C. to 100° C. for several seconds to several tens of minutes in the atmosphere and a heat treatment at a temperature of 0° C. to 80° C. under reduced pressure for ten minutes to several hours.

In addition, a baking method after the drying is not particularly limited since it varies depending on the polymer material to be used; but in a case where a polyimide resin is used, examples thereof include a treatment of heating at a temperature of 160° C. to 240° C. for 2 minutes to 60 minutes, and in a case where an epoxy resin is used, examples thereof include a treatment of heating at a temperature of 30° C. to 80° C. for 2 minutes to 60 minutes.

The present invention is basically configured as described above. The laminate according to the embodiment of the present invention has been described in detail above, but the present invention is not limited to the above-described embodiments, and various improvements and changes can be made without departing from the spirit of the present invention.

### EXAMPLES

Hereinafter, the characteristics of the present invention will be described in detail by Examples. The materials, reagents, amounts and proportions of substances, operations, and the like described in the following examples can be appropriately modified as long as the gist of the present invention is maintained. Therefore, the scope of the present invention is not limited to Examples shown below.

In the present example, laminates of Examples 1 to 10 and laminates of Comparative Examples 1 to 3 were produced. For the laminates of Examples 1 to 10 and the laminates of Comparative Examples 1 to 3, peeling of the individualized anisotropically conductive members was evaluated as an indicator for handling the individualized anisotropically conductive members. The evaluation results of the peeling of the individualized anisotropically conductive members are shown in Table 1 below. Furthermore, the bonding of the individualized anisotropically conductive members was evaluated.

Next, the evaluation of the peeling of the individualized anisotropically conductive members and the evaluation of the bonding of the individualized anisotropically conductive members will be described.

### Peeling of Individualized Anisotropically Conductive Member

With the produced laminate, the anisotropically conductive member was cut into a size of 10 mm×10 mm. After the cutting, the laminate was heated in the atmosphere at a temperature of 110° C. for 1 minute to foam the heat-peeling type adhesive layer, and the individualized anisotropically conductive member having a size of 10 mm×10 mm was peeled off. A success rate of the peeling of the individualized anisotropically conductive member in this case was evaluated according to the following evaluation standard.

The successful peeling of the individualized anisotropically conductive member means that the anisotropically conductive member was able to be peeled off from the adhesive layer in a case where the individualized anisotropically conductive member was vacuum-suctioned at −80 kPa (gauge pressure) using a head (10 mm×10 mm, diameter of the suction hole: 1 mm) of a flip chip bonding device (FC3000 manufactured by Toray Engineering Co., Ltd.).

### Evaluation Standard

A: success rate of the peeling was 100%.
B: success rate of the peeling was 95% or more and less than 100%.
C: success rate of the peeling was 85% or more and less than 95%.
D: success rate of the peeling was less than 85%.

The following cutting device was used for cutting the laminate.

As the cutting device, DAD3230 (product name) manufactured by DISCO Corporation was used. The anisotropically conductive member including the resin base material with a pressure-sensitive adhesive layer was cut into a size of 10 mm×10 mm at a rotation speed of 1,500 rpm (revolution per minute) and a feed speed of 0.5 mm/sec.

### Bonding of Individualized Anisotropically Conductive Member

The evaluation of the bonding will be described.

A test element group chip (TEG chip) which could evaluate daisy chain was prepared. The TEG chip was assumed to have 1,000 daisy chains.

The anisotropically conductive members were laminated with two TEG chips and installed in a chamber of a wafer bonder. After the inside of the chamber was once vacuumed to 10⁻³ Pa, a nitrogen gas containing 5% hydrogen was introduced into the chamber to stabilize the pressure inside the chamber at 5 KPa. Thereafter, pressurizing and heating were carried out under conditions of a pressure of 20 MPa and a temperature of 200° C., and held for 30 minutes for the bonding.

The bonding was evaluated according to the following evaluation standard.

### Evaluation Standard

A: among the 1,000 daisy chains of the bonded product, all of them were connected.
B: among the 1,000 daisy chains of the bonded product, 75% or more and less than 100% thereof were connected.
C: among the 1,000 daisy chains of the bonded product, 50% or more and less than 75% thereof were connected.
D: among the 1,000 daisy chains of the bonded product, 25% or more and less than 50% thereof were connected.

Hereinafter, the method of measuring the average value of the total crack length per unit area of the individualized anisotropically conductive member will be described.

Since the anisotropically conductive member did not transmit infrared rays, the cracks of the anisotropically conductive member could be clearly detected by the infrared rays.

A semiconductor/FPD inspection microscope MX61 (trade name) manufactured by Olympus Corporation was used as an infrared microscope. An objective lens LMRLN5XIR (trade name) for near infrared region (700 nm to 1300 nm) observation manufactured by Olympus Corporation was used as a lens. In addition, an automatic XY stage for an upright microscope manufactured by Mettler-Toledo International Inc. was used as a stage.

An inspection image of the entire plan view of the semiconductor device was acquired using the infrared microscope, and the acquired inspection image was subjected to a binarization process to obtain a binarized image of the inspection image. A length of the black portion of the binarized image was measured. Cracks were extracted from the black portion with a threshold value of 10 μm. The total length of the extracted cracks was obtained. In addition, the area of the binarized image was obtained from the visual field area. The total crack length per unit area was obtained from the crack length and the area of the binarized image. Next, the average value of the total crack length per unit area was obtained.

In addition, in the semiconductor device, an electrode connection region connected to an electrode and an electrode non-connection region not connected to an electrode were specified in advance. The average value of the total crack length per unit area in the electrode connection region connected to an electrode is defined as an electrode part crack length, and the average value of the total crack length per unit area in the electrode non-connection region not connected to an electrode is defined as a non-electrode part crack length.

In Examples 1 to 10 and Comparative Examples 1 to 3, for those without the cracks, “-” is indicated in the columns of “Non-electrode part crack length” and “Electrode part crack length” in Table 1 below.

Hereinafter, Examples 1 to 10 and Comparative Examples 1 to 3 will be described.

### Example 1

A laminate of Example 1 will be described.

### Metal-Filled Microstructure

### Production of Aluminum Substrate

A molten metal was produced using an aluminum alloy containing 0.06% by mass of Si, 0.30% by mass of Fe, 0.005% by mass of Cu, 0.001% by mass of Mn, 0.001% by mass of Mg, 0.001% by mass of Zn, and 0.03% by mass of Ti and, as the remainder, Al and unavoidable impurities, a molten metal treatment and filtration were performed, and an ingot having a thickness of 500 mm and a width of 1,200 mm was produced according to a direct chill (DC) casting method.

Next, the surface was scraped off using a surface grinder having an average thickness of 10 mm and heated at 550° C. and maintained the state for approximately 5 hours. After the temperature was decreased to 400° C., a rolled sheet having a thickness of 2.7 mm was obtained using a hot rolling mill.

Furthermore, the rolled plate was subjected to a heat treatment at 500° C. using a continuous annealing machine, and then subjected to cold rolling to be finished to a thickness of 1.0 mm, thereby obtaining an aluminum substrate in accordance to JIS 1050 Material.

The aluminum substrate was formed into a wafer shape with a diameter of 200 mm (8 inches), and then subjected to each of the following treatments.

### Electropolishing Treatment

The above-described aluminum substrate was subjected to an electropolishing treatment using an electropolishing liquid having the following formulation under conditions of a voltage of 25 V, a liquid temperature of 65° C., and a liquid flow rate of 3.0 m/min.

A carbon electrode was used as a cathode, and GP0110-30R (manufactured by TAKASAGO Ltd.) was used as a power source. In addition, the flow rate of the electrolytic solution was measured using a vortex flow monitor FLM22-10PCW (manufactured by AS ONE Corporation).

(Formulation of electropolishing liquid)

| | |
|---|---|
| 85% by mass of phosphoric acid (reagent manufactured | 660 mL |
| by FUJIFILM Wako Pure Chemical Corporation) | |
| Pure water | 160 mL |
| Sulfuric acid | 150 mL |
| Ethylene glycol | 30 mL |

### Anodization Treatment Step

Next, the aluminum substrate after the electropolishing treatment was subjected to an anodization treatment by a self-ordering method according to the procedure described in JP2007-204802A.

The aluminum substrate after the electropolishing treatment was subjected to a pre-anodization treatment for 5 hours using an electrolytic solution of 0.50 mol/L oxalic acid under conditions of a voltage of 40 V, a liquid temperature of 16° C., and a liquid flow rate of 3.0 m/min.

Thereafter, the aluminum substrate subjected to the pre-anodization treatment was dipped for 12 hours in a mixed aqueous solution (liquid temperature: 50° C.) of 0.2 mol/L of chromic acid anhydride and 0.6 mol/L phosphoric acid to perform a film removal treatment.

Thereafter, the aluminum substrate was subjected to a re-anodization treatment for 3 hours and 45 minutes using an electrolytic solution of 0.50 mol/L oxalic acid under conditions of a voltage of 40 V, a liquid temperature of 16° C., and a liquid flow rate of 3.0 m/min to obtain an anodized film having a thickness of 30 μm.

In the pre-anodization treatment and the re-anodization treatment, a stainless steel electrode was used as a cathode, and GP0110-30R (manufactured by TAKASAGO Ltd.) was used as a power source. In addition, NeoCool BD36 (manufactured by Yamato Scientific Co., Ltd.) was used as a cooling device, and PAIRSTIRRER PS-100 (manufactured by TOKYO RIKAKIKAI CO., LTD.) was used as a stirring and heating device. Furthermore, the flow rate of the electrolytic solution was measured using a vortex flow monitor FLM22-10PCW (manufactured by AS ONE Corporation).

### Barrier Layer Removing Step

Next, an electrolytic treatment (electrolytic removal treatment) was carried out while continuously lowering the voltage from 40 V to 0 V at a voltage lowering rate of 0.2 V/sec under the same treatment liquid and treatment conditions as those of the above-described anodization treatment.

Thereafter, an etching treatment (etching removal treatment) of dipping in 5% by mass phosphoric acid at 30° C. for 30 minutes was carried out to remove the barrier layer in the bottom portion of the micropores of the anodized film, and the aluminum substrate was exposed through the micropores.

Here, an average opening diameter of the micropores present in the anodized film after the barrier layer removing step was 60 nm. The average opening diameter was obtained by acquiring a surface image at a magnification of 50,000 times using a field emission scanning electron microscope (FE-SEM), selecting 50 micropores in the surface image, and measuring diameters of portions corresponding to the opening for each of the selected 50 micropores. An average value of the diameters of the portions corresponding to the openings of the measured micropores was calculated. The average value was defined as the average opening diameter.

In addition, an average thickness of the anodized film after the barrier layer removing step was 80 μm. For the average thickness, the anodized film was machined in the thickness direction using a focused ion beam (FIB), and an image of a cross section thereof was acquired at a magnification of 50,000 times with a field emission scanning electron microscope (FE-SEM). In the cross-sectional image, lengths of 10 portions corresponding to the thickness of the anodized film were measured, and an average value of the lengths of the 10 measured portions was obtained. The average value was defined as the average thickness of the anodized film after the barrier layer removing step.

In addition, a density of the micropores present in the anodized film was approximately 100 million/mm². The density of the micropores was measured and calculated by a method described in paragraphs [0168] and [0169] of JP2008-270158A.

In addition, a degree of regularity of the micropores present in the anodized film was 92%. The degree of regularity was measured and calculated by acquiring a surface image at a magnification of 20,000 times using a field emission scanning electron microscope (FE-SEM) by a method described in paragraphs [0024] to [0027] of JP2008-270158A.

### Metal Filling Step

Next, the aluminum substrate was used as a cathode, and platinum was used as a positive electrode for an electrolytic plating treatment.

Specifically, a copper plating liquid having the following formulation was used, and by carrying out electrolytic plating under constant current, a metal-filled microstructure in which the inside of the pores (micropores) was filled with copper to form a conduction path was produced.

Here, for the constant current electrolysis, a plating device manufactured by YAMAMOTO-MS Co., Ltd. was used, and a power source (HZ-3000) manufactured by HOKUTO DENKO Corporation was used, cyclic voltammetry was carried out in the plating liquid, and then after checking precipitation potential, the treatment was carried out under the conditions shown below.

(Formulation and conditions of copper plating liquid)

| | | |
|---|---|---|
| Copper sulfate | 100 | g/L |
| Sulfuric acid | 50 | g/L |
| Hydrochloric acid | 15 | g/L |
| Temperature | 25° | C. |
| Current density | 10 | A/dm² |

### Polishing Step

Next, the front surface of the anodized film of the metal-filled microstructure in which the conduction path filled with the metal was formed was subjected to a CMP treatment, and polished by 5 μm from the surface to smoothen the surface. As a CMP slurry, PNANERLITE-7000 manufactured by Fujimi Incorporated. was used.

The front surface of the anodized film after filling the pores (micropores) with the metal was observed with a field emission scanning electron microscope (FE-SEM), and in a case where the presence or absence of sealing with metal in 1,000 micropores was observed to calculate a sealing rate (the number of micropores to be sealed/1000), it was 96%.

In addition, in a case where the anodized film after filling the pores (micropores) with the metal was machined with FIB in the thickness direction and an image of a cross section was acquired at a magnification of 50,000 times with a field emission scanning electron microscope (FE-SEM) to confirm the inside of the micropores, it was confirmed that the inside of the sealed pores (micropores) was completely filled with the metal.

### Trimming Step

The metal-filled microstructure after the polishing step was dipped in an aqueous solution of sodium hydroxide (concentration: 5% by mass, liquid temperature: 20° C.), the dipping time was adjusted such that a height of the protruding portion was 500 nm, a surface of the aluminum anodized film was selectively dissolved, and then the aluminum was washed with water and dried to leave protruding copper columns as conduction paths.

### Substrate Removing Step

Next, the aluminum substrate was dipped in a 20% by mass mercury chloride aqueous solution (mercury vapor) at 20° C. for 3 hours to dissolve and remove the aluminum substrate, thereby producing a metal-filled microstructure.

### Resin Substrate Forming Step

Next, a resin base material with a heat-peeling type pressure-sensitive adhesive layer (REVALPHA 3195MS, manufactured by Nitto Denko Corporation) was attached to a silicon wafer having a diameter of 200 mm (8 inches), and the metal-filled microstructure was attached thereon. In this case, the metal-filled microstructure was attached with the large diameter side of the conduction paths facing the pressure-sensitive adhesive layer.

### Polishing Step

Next, the surface of the metal-filled microstructure on the small diameter side of the conduction path, that is, the back surface of the anodized film was subjected to a CMP treatment to smooth the metal-filled microstructure. As a CMP slurry, PNANERLITE-7000 manufactured by Fujimi Incorporated. was used.

In this case, the polishing amount was adjusted such that a value of small diameter/large diameter was 0.98. The polishing amount was adjusted by the polishing time.

### Trimming Step

The metal-filled microstructure after the substrate removing step was dipped in an aqueous solution of sodium hydroxide (concentration: 5% by mass, liquid temperature: 20° C.), the dipping time was adjusted such that a height of the protruding portion was 500 nm, a surface of the aluminum anodized film was selectively dissolved, and then the aluminum was washed with water and dried to leave protruding copper columns as conduction paths.

### Pressure-Sensitive Adhesive Layer Forming Step

A resin layer was formed on the metal-filled microstructure after the trimming step by the method shown below to produce a laminate.

### Resin Layer

LTC9320 (manufactured by FUJIFILM Electronic Materials Co., Ltd.) was used as a commercially available product of a polyamic acid ester solution (containing dimethyl sulfoxide, trialkoxysilane carboxysilane, and an oxime derivative) in which γ-butyrolactone was used as a solvent.

The solution was applied onto a surface of an insulating base material on which the conduction path protruded, dried to form a film, and then subjected to an imidization reaction at 200° C. for 3 hours in a nitrogen-purged reaction furnace (oxygen concentration: 10 ppm or less), thereby forming a pressure-sensitive adhesive layer having a thickness of 500 nm and consisting of a polyimide resin layer. A thickness of the resin layer was adjusted by adding a solvent (methyl ethyl ketone (MEK)).

### Example 2

Example 2 is different from Example 1 in that the value of small diameter/large diameter was 0.95. The other conditions were the same as those in Example 1.

In Example 2, the polishing amount of the front surface of the anodized film was reduced and the polishing amount of the back surface of the anodized film was increased as compared with Example 1, the thickness of the anodized film was set to be the same as that of Example 1, and the value of small diameter/large diameter was set to 0.95.

### Example 3

Example 3 is different from Example 1 in that the value of small diameter/large diameter was 0.9. The other conditions were the same as those in Example 1.

In Example 3, the polishing amount of the front surface of the anodized film was reduced and the polishing amount of the back surface of the anodized film was increased as compared with Example 1, the thickness of the anodized film was set to be the same as that of Example 1, and the value of small diameter/large diameter was set to 0.9.

### Example 4

Example 4 is different from Example 1 in that the value of small diameter/large diameter was 0.85. The other conditions were the same as those in Example 1.

In Example 4, the polishing amount of the front surface of the anodized film was reduced and the polishing amount of the back surface of the anodized film was increased as compared with Example 1, the thickness of the anodized film was set to be the same as that of Example 1, and the value of small diameter/large diameter was set to 0.85.

### Example 5

Example 5 is different from Example 1 in that the value of small diameter/large diameter was 0.6. The other conditions were the same as those in Example 1.

In Example 5, the polishing amount of the front surface of the anodized film was reduced and the polishing amount of the back surface of the anodized film was increased as compared with Example 1, the thickness of the anodized film was set to be the same as that of Example 1, and the value of small diameter/large diameter was set to 0.6.

### Example 6

Example 6 is different from Example 1 in that the value of small diameter/large diameter was 0.5. The other conditions were the same as those in Example 1.

In Example 6, the polishing amount of the front surface of the anodized film was reduced and the polishing amount of the back surface of the anodized film was increased as compared with Example 1, the thickness of the anodized film was set to be the same as that of Example 1, and the value of small diameter/large diameter was set to 0.5.

### Example 7

Example 7 is different from Example 1 in that the value of small diameter/large diameter was 0.2. The other conditions were the same as those in Example 1.

In Example 7, the polishing amount of the front surface of the anodized film was reduced and the polishing amount of the back surface of the anodized film was increased as compared with Example 1, the thickness of the anodized film was set to be the same as that of Example 1, and the value of small diameter/large diameter was set to 0.2.

### Example 8

Example 8 is different from Example 1 in that the value of small diameter/large diameter was 0.1. The other conditions were the same as those in Example 1.

In Example 8, the polishing amount of the front surface of the anodized film was reduced and the polishing amount of the back surface of the anodized film was increased as compared with Example 1, the thickness of the anodized film was set to be the same as that of Example 1, and the value of small diameter/large diameter was set to 0.1.

### Example 9

Example 9 is different from Example 4 in that the non-electrode part crack length was 1 (μm/mm²) and the electrode part crack length was 1 (μm/mm²). The other conditions were the same as those in Example 4.

### Example 10

Example 10 is different from Example 4 in that the non-electrode part crack length was 5 (μm/mm²) and the electrode part crack length was 1 (μm/mm²). The other conditions were the same as those in Example 4.

### Comparative Example 1

Comparative Example 1 is different from Example 1 in that the value of small diameter/large diameter was 1.0. The other conditions were the same as those in Example 1.

In Comparative Example 1, the polishing amount of the front surface of the anodized film was increased and the polishing amount of the back surface of the anodized film was reduced as compared with Example 1, the thickness of the anodized film was set to be the same as that of Example 1, and the value of small diameter/large diameter was set to 1.0.

### Comparative Example 2

Comparative Example 2 is different from Comparative Example 1 in that the non-electrode part crack length was 1 (μm/mm²) and the electrode part crack length was 1 (μm/mm²). The other conditions were the same as those in Comparative Example 1.

### Comparative Example 3

Comparative Example 3 is different from Comparative Example 1 in that the non-electrode part crack length was 5 (μm/mm²) and the electrode part crack length was 1 (μm/mm²). The other conditions were the same as those in Comparative Example 1.

TABLE 1

| | Value | Non- | Electrode | | |
|---|---|---|---|---|---|
| | of small | electrode | part | | |
| | diameter/large | part crack | crack | Success | |
| | diameter | length | length | rate of | Bond- |
| | (—) | (μm/mm²) | (μm/mm²) | peeling | ing |
| Example 1 | 0.98 | — | — | C | A |
| Example 2 | 0.95 | — | — | B | A |
| Example 3 | 0.9 | — | — | B | A |
| Example 4 | 0.85 | — | — | A | A |
| Example 5 | 0.6 | — | — | A | A |
| Example 6 | 0.5 | — | — | A | A |
| Example 7 | 0.2 | — | — | A | A |
| Example 8 | 0.1 | — | — | A | A |
| Example 9 | 0.85 | 1 | 1 | A | B |
| Example 10 | 0.85 | 5 | 1 | A | B |
| Comparative | 1.0 | — | — | D | B |
| Example 1 | | | | | |
| Comparative | 1.0 | 1 | 1 | D | D |
| Example 2 | | | | | |
| Comparative | 1.0 | 5 | 1 | D | D |
| Example 3 | | | | | |

As shown in Table 1, in Examples 1 to 10, the individualized anisotropically conductive member was easily removed, the success rate of the peeling was high, and further, favorable results were obtained for the bonding, as compared with Comparative Examples 1 to 3.

In Comparative Examples 1 to 3, since the value of small diameter/large diameter was 1.0, that is, the diameter of the conduction path was uniform, and the individualized anisotropically conductive member did not warp, many of them were difficult to remove and could not be peeled off.

From Examples 1 to 10, in a case where the values of small diameter/large diameter were in a range of 0.1 to 0.95, the peelability was improved and the success rate of the peeling was increased, which is preferable. In a case where the value of small diameter/large diameter was in a range of 0.1 to 0.85, the peelability was further improved and the success rate of the peeling was further increased, which is more preferable. In a case where the value of small diameter/large diameter was more than 0.5 and 0.85 or less, the success rate of the peeling was high, and the quality of the individualized anisotropically conductive member after taking out was favorable.

In addition, from Examples 4, 9, and 10, the success rate of the peeling was high even in a case where the cracks were present, but the bonding was better in a case where the cracks were not present.

### EXPLANATION OF REFERENCES

10, 11: laminate
12: support
12a, 14a, 20a, 40a, 44a: front surface
14: adhesive layer
16, 16a, 17: anisotropically conductive member
18: resin layer
20: insulating base material
20b, 44b: back surface
21: pore
22: conduction path
22a, 22b: protruding portion
22c: side surface
23: crack
30: metal layer
32: bonding member
40: aluminum substrate
42c: bottom portion
42d: surface
43: barrier layer
44: anodized film
45, 45b: metal
45a: metal layer
Da, Db: diameter
Ds: lamination direction
Dt: thickness direction
hj, hm: average thickness
ht: thickness
p: center-to-center distance
x: direction
w: interval

What is claimed is:

1. A laminate comprising:
a support;
an adhesive layer; and
an anisotropically conductive member,
wherein the support, the adhesive layer, and the anisotropically conductive member are laminated in this order,
the anisotropically conductive member has an insulating base material having electrical insulating properties and a plurality of conduction paths which penetrate in a thickness direction of the insulating base material and are provided in a state of being electrically insulated from each other,
the insulating base material is an anodized film of a valve metal,
each of the plurality of the conduction paths is composed of a conductive substance, in which a diameter of one surface in the thickness direction of the insulating base material is different from a diameter of the other surface in the thickness direction of the insulating base material,
in a case where a value of small diameter/large diameter, which is a ratio of a small diameter and a large diameter between the diameter of the one surface of the conduction path and the diameter of the other surface of the conduction path, is denoted by R, 0.5≤R≤0.85 is satisfied, and
the anisotropically conductive member is laminated such that a surface on a side having the large diameter between the diameter of the one surface of the conduction path and the diameter of the other surface of the conduction path faces the adhesive layer.

2. The laminate according to claim 1,
wherein an adhesive force of the adhesive layer decreases in a specific temperature range, or decreases due to ultraviolet rays.

3. The laminate according to claim 2,
wherein the adhesive force of the adhesive layer decreases at a temperature of 110° C. or higher.

4. The laminate according to claim 1,
wherein a density of the conduction paths in the one surface and the other surface of the insulating base material is 1×10⁶ to 1×10¹⁰/mm², and the diameter of the one surface of the conduction path and the diameter of the other surface of the conduction path is 10 nm or more and 500 nm or less.

5. The laminate according to claim 2,
wherein a density of the conduction paths in the one surface and the other surface of the insulating base material is 1×10⁶ to 1×10¹⁰/mm², and the diameter of the one surface of the conduction path and the diameter of the other surface of the conduction path is 10 nm or more and 500 nm or less.

6. The laminate according to claim 3,
wherein a density of the conduction paths in the one surface and the other surface of the insulating base material is 1×10⁶ to 1×10¹⁰/mm², and the diameter of the one surface of the conduction path and the diameter of the other surface of the conduction path is 10 nm or more and 500 nm or less.

7. The laminate according to claim 1,
wherein a thickness of the insulating base material is 10 μm or more and 30 μm or less.

8. The laminate according to claim 2,
wherein a thickness of the insulating base material is 10 μm or more and 30 μm or less.

9. The laminate according to claim 3,
wherein a thickness of the insulating base material is 10 μm or more and 30 μm or less.

10. The laminate according to claim 1,
wherein the support is a bonding member having a metal layer, and the metal layer is exposed from the adhesive layer.

11. The laminate according to claim 2,
wherein the support is a bonding member having a metal layer, and the metal layer is exposed from the adhesive layer.

12. The laminate according to claim 3,
wherein the support is a bonding member having a metal layer, and the metal layer is exposed from the adhesive layer.

13. The laminate according to claim 1,
wherein the anisotropically conductive member has a crack in the insulating base material.

14. The laminate according to claim 2,
wherein the anisotropically conductive member has a crack in the insulating base material.

15. The laminate according to claim 3,
wherein the anisotropically conductive member has a crack in the insulating base material.

16. The laminate according to claim 1,
wherein the conduction path has a protruding portion which protrudes from at least one surface of facing surfaces of the insulating base material in the thickness direction.

17. The laminate according to claim 2,
wherein the conduction path has a protruding portion which protrudes from at least one surface of facing surfaces of the insulating base material in the thickness direction.

18. The laminate according to claim 3,
wherein the conduction path has a protruding portion which protrudes from at least one surface of facing surfaces of the insulating base material in the thickness direction.
